(19) United States
(12) Patent Application Publication
(10) Pub. No.: US 2026/0229776 A1
(43) Pub. Date: Aug. 6, 2026

(54) SIGNAL ADJUSTMENT COMPONENT, ANTENNA, AND COMMUNICATION DEVICE

(71) Applicant: HUAWEI TECHNOLOGIES CO., LTD., Shenzhen (CN)

(72) Inventors: Huabing Su, Dongguan (CN); Guanchu Liu, Dongguan (CN); Yuzhi Ding, Dongguan (CN); Jiaming Li, Shenzhen (CN); Maobin Li, Dongguan (CN); Yiwei Wu, Shenzhen (CN)

(21) Appl. No.: 19/630,584

(22) Filed: Mar. 27, 2026

Related U.S. Application Data
(63) Continuation of application No. PCT/CN2024/122085, filed on Sep. 28, 2024.

(30) Foreign Application Priority Data
Sep. 28, 2023 (CN) 202311292283.7

(51) Int. Cl. H01Q 3/32; H01P 3/08; H01Q 1/24; H05K 1/02

(52) U.S. Cl. CPC H01Q 3/32; H01P 3/08; H01Q 1/246; H05K 1/0243; H05K 2201/10053; H05K 2201/10098

(57) ABSTRACT

A signal adjustment component includes a motherboard with a plurality of lines, a driving component, and a plurality of switching components. The switching component is movably assembled on the motherboard, and an auxiliary stripline is disposed on the switching component. The driving component includes a plurality of driving parts, one driving part is in driving connection to one switching component, and the driving part drives the corresponding switching component to move to a first location, where the auxiliary stripline and a line form a first circuit state, or a second location, where the auxiliary stripline and a line form a second circuit state. The plurality of switching components and the plurality of driving parts is arranged in the sliding direction. When the driving component is located at a preset location, distances between switching components and driving parts in at least two driving combinations in the sliding direction are different.

### CROSS-REFERENCE TO RELATED APPLICATIONS

This application is a continuation of International Application No. PCT/CN2024/122085, filed on Sep. 28, 2024, which claims priority to Chinese Patent Application No. 202311292283.7, filed on Sep. 28, 2023. The disclosures of the aforementioned applications are hereby incorporated by reference in their entireties.

### TECHNICAL FIELD

The disclosure relates to the field of communication technologies, and more specifically, to a signal adjustment component, an antenna, and a communication device.

### BACKGROUND

Signal coverage scenarios of mobile communication are complex and diversified, for example, may include scenarios covering a dense commercial area or a residential area, an open rural area, and a long and narrow high-speed railway tunnel. Different coverage scenarios have different requirements on antenna signal coverage. For example, requirements on widths, strength, or the like of an antenna beam are different, and locations and quantities of existing signal coverage holes are different. If signal coverage is optimized and the coverage holes are filled by simply adding sites, problems such as low coverage efficiency and increased costs may be caused. Therefore, equipping a communication device with an adjustment capability is an important development direction at present. A structure of an adjustment component in the conventional technology is complex, and one adjustment component can implement only switching between two states of the communication device. Consequently, scenarios for adjustment are monotonous.

### SUMMARY

The disclosure is directed toward a signal adjustment component, an antenna, and a communication device. The signal adjustment component can perform multi-level adjustment, to enrich application scenarios of the antenna.

According to an exemplary embodiment, the signal adjustment component includes a motherboard, a driving component, and a plurality of switching components. A line is disposed on a surface of the motherboard, and the line may be specifically configured to connect to a radiating element and a connection port. Each switching component is movably assembled on the motherboard, and an auxiliary stripline is disposed on each switching component. Each switching component is configured to change a connection status with the line via the auxiliary stripline during motion. Specifically, for any switching component, an auxiliary stripline moves with the switching component; when the switching component is located at a first location, the auxiliary stripline and a line form a first circuit state; and when the switching component is located at a second location, the auxiliary stripline and the line form a second circuit state. The first location and the second location mainly indicate different locations of the switching component. The first circuit state is different from the second circuit state. The driving component is slidably assembled on the motherboard, and the driving component drives the switching component to be switched between the first location and the second location in a sliding process of the motherboard. Specifically, the driving component includes a plurality of driving parts, the plurality of driving parts one-to-one correspond to the plurality of switching components, one driving part and one switching component that correspond to each other are in driving connection to form a driving combination, and the driving part in the driving combination is configured to drive the switching component to move. Specifically, the driving part drives the switching component in the same driving combination to move to the corresponding first location or second location. The plurality of switching components is arranged in a sliding direction of the driving component, and the plurality of driving parts is also arranged in the sliding direction. When the driving component is located at a preset location, distances between switching components and driving parts in at least two driving combinations in the sliding direction are different. When the driving component slides to different locations in the sliding direction, switching components in different driving combinations are driven to move. According to an exemplary embodiment, one driving component drives different switching components to move, to implement multi-level switch adjustment, so that an antenna can present a large quantity of operating states, and is more flexibly used in a more complex signal coverage scenario, thereby meeting a customer's antenna requirements in multiple scenarios.

The signal adjustment component includes a motherboard, a driving component, and a plurality of switching components. A plurality of lines is disposed on a surface of the motherboard. Each switching component is movably assembled on the motherboard, and an auxiliary stripline is disposed on each switching component. For any switching component, when the switching component is located at a first location, an auxiliary stripline and a line form a first circuit state; and when the switching component is located at a second location, the auxiliary stripline and the line form a second circuit state. The driving component is slidably assembled on the motherboard, the driving component includes a plurality of driving parts, one driving part is in driving connection to one switching component to form a driving combination, and the driving part in the driving combination drives the switching component to move to the corresponding first location or second location. The plurality of switching components is arranged in a sliding direction of the driving component, and the plurality of driving parts is also arranged in the sliding direction. When the driving component is located at a preset location, distances between switching components and driving parts in at least two driving combinations in the sliding direction are different. When the driving component slides to different locations in the sliding direction, switching components in different driving combinations are driven to move.

There may be a plurality of options for a translational switching component. For example, in a technical solution, the switching component includes a translational switching component, and the translational switching component moves in a preset plane without rotation. A plurality of sliding slots is disposed on the motherboard, and the translational switching component is slidably assembled in the sliding slot. For ease of description, it is considered that two ends of the sliding slot are respectively a first end and a second end. The driving part includes a first driving part. The first driving part is adapted to the translational switching component, and is configured to drive the translational switching component to move. The first driving part specifically includes a first oblique end surface and a second oblique end surface that are parallel to a first plane, and correspondingly, the translational switching component includes a third oblique end surface and a fourth oblique end surface that are parallel to the first plane. When the driving component slides to a first preset location in a first direction, the first oblique end surface abuts against the third oblique end surface, and the driving component continues to slide in the first direction, to drive the translational switching component to slide in the sliding slot in a direction from the first end to the second end until the auxiliary stripline and the line form the first circuit state. When the driving component slides to a second preset location in a second direction, the second oblique end surface abuts against the fourth oblique end surface, and the driving component continues to slide in the second direction, to drive the translational switching component to slide in the sliding slot in a direction from the second end to the first end until the auxiliary stripline and the line form the second circuit state. Specifically, the first direction and the second direction are parallel to the sliding direction, the first direction is opposite to the second direction, and the first plane intersects the sliding direction.

To implement multi-level driving of the switching component, when the driving component is located at the preset location, distances between first oblique end surfaces and third oblique end surfaces in the at least two driving combinations in the first direction are different.

To improve sliding stability of the switching component and facilitate stable maintenance of the first circuit state and the second circuit state, the first driving part includes a first limiting surface and a second limiting surface that are parallel to the sliding direction, and correspondingly, the translational switching component includes a third limiting surface and a fourth limiting surface that are arranged in the direction from the first end to the second end. When the translational switching component moves to a first location, the first limiting surface and the third limiting surface abut against each other in a third direction and are capable of sliding relative to each other in the sliding direction, where the third direction is perpendicular to the sliding direction. The first limiting surface abuts against the third limiting surface in the third direction, and the translational switching component is limited, so that the auxiliary stripline and the line stably remain in the first circuit state. When the driving component limits the translational switching component, the translational switching component does not affect sliding of the driving component, and the driving component may continue to slide, to drive another switching component to move. When the translational switching component moves to a second location, the second limiting surface and the fourth limiting surface abut against each other in the third direction and are capable of sliding relative to each other in the sliding direction. The second limiting surface abuts against the fourth limiting surface in the third direction, and the translational switching component is limited, so that the auxiliary stripline and the line stably remain in the second circuit state. When the driving component limits the translational switching component, the translational switching component does not affect sliding of the driving component, and the driving component may continue to slide, to drive another switching component to move.

To implement multi-level control of the plurality of switching components of the signal adjustment component, in the at least two driving combinations, lengths of first limiting surfaces of the driving parts in the sliding direction are different, and lengths of second limiting surfaces in the sliding direction are also different. In a process of driving different switching components to move, the driving component may slide relative to another switching component, to ensure multi-level control of the switching component of the signal adjustment component.

According to an exemplary embodiment, the switching component includes a rotating switching component, the rotating switching component is rotatably assembled on the motherboard via a rotating shaft, and the rotating switching component rotates under driving of the driving component. Specifically, the rotating switching component includes a first driving plane and a second driving plane that are parallel to an axial direction of the rotating shaft, the first driving plane and the second driving plane intersect at a preset angle, and the first driving plane and the second driving plane are sequentially arranged in the axial direction, that is, the first driving plane and the second driving plane are located in a two-layer structure that is of the rotating switching component and that is arranged in the axial direction. Correspondingly, the driving part includes a second driving part, the second driving part includes a first driving surface and a second driving surface, the first driving surface and the second driving surface are sequentially arranged in the axial direction, and the first driving surface and the second driving surface separately extend in a direction away from the rotating shaft. The first driving surface and the first driving plane are located at a same layer, and the second driving surface and the second driving plane are located at a same layer. When the driving component slides to a third preset location in the first direction, the first driving surface abuts against the first driving plane, the driving component continues to slide in the first direction, and the first driving surface drives the first driving plane to rotate, to further drive the rotating switching component to rotate by the preset angle in a first circumferential direction to the first location. When the driving component slides to a fourth preset location in the second direction, the second driving surface abuts against the second driving plane, the driving component continues to slide in the second direction, and the second driving surface drives the second driving plane to rotate, to further drive the rotating switching component to rotate by the preset angle in a second circumferential direction to the second location. If the first circumferential direction is opposite to the second circumferential direction, when the driving component slides in the first direction, the rotating switching component is driven to rotate in the first circumferential direction, and when the driving component slides in the second direction, the rotating switching component is driven to rotate in the second circumferential direction. In this case, when the driving component slides in an opposite direction, the rotating switching component rotates in the opposite direction.

To implement multi-level control of the plurality of switching components of the signal adjustment component, when the driving component is located at the preset location, distances between first driving surfaces and rotating shafts in the at least two driving combinations in the first direction are different. Therefore, when the driving component slides to different locations in the first direction or the second direction, different rotating switching components may be separately driven to rotate.

Moreover, the first driving surface and the second driving surface of the second driving part are axisymmetrically disposed, and a symmetry axis of the first driving surface and the second driving surface is parallel to the axial direction. Fitting between the second driving part and the rotating switching component in a case in which the driving component slides in the first direction is the same as that between the second driving part and the rotating switching component in a case in which the driving component slides in the second direction. This helps simplify a structure of the second driving part and a structure of the rotating switching component.

To improve sliding stability of the switching component and facilitate stable maintenance of the first circuit state and the second circuit state, the driving part includes a fifth limiting surface and a sixth limiting surface that are parallel to the sliding direction, and the fifth limiting surface and the sixth limiting surface are sequentially arranged in the axial direction. The fifth limiting surface and the first driving surface are located at a same layer, and the sixth limiting surface and the second driving surface are located at a same layer. When the rotating switching component rotates to the first location, the fifth limiting surface is parallel to and abuts against the first driving plane, so that the auxiliary stripline and the line stably remain in the first circuit state. When the rotating switching component rotates to the second location, the sixth limiting surface is parallel to and abuts against the second driving plane, so that the auxiliary stripline and the line stably remain in the second circuit state.

The fifth limiting surface is connected to the first driving surface, and the first driving plane may continuously move between the fifth limiting surface and the first driving surface. The sixth limiting surface is connected to the second driving surface, and the second driving plane may continuously move between the sixth limiting surface and the second driving surface.

There is a plurality of options for the first driving surface and the second driving surface provided. For example, the first driving surface may be at least one of a plane, a paraboloid, or a semi-cylindrical surface. The second driving surface may be at least one of a plane, a paraboloid, or a semi-cylindrical surface. In conclusion, there is an included angle between the first driving surface and the fifth limiting surface, and there is an included angle between the second driving surface and the sixth limiting surface.

Because the rotating switching component rotates relative to the motherboard, the auxiliary stripline disposed on the rotating switching component is an arc-shaped auxiliary stripline, an area that is of the line and that corresponds to the rotating switching component includes an arc-shaped line, and the arc-shaped auxiliary stripline and the arc-shaped line form a first circuit state or a second circuit state. The arc-shaped auxiliary stripline rotates with rotation of the rotating switching component. This helps improve reliability of a connection between the arc-shaped auxiliary stripline and the arc-shaped line.

The signal adjustment component provided in the foregoing technical solution may be used in different scenarios. In an application scenario, a beam of the antenna is adjusted by using the signal adjustment component. Specifically, one line disposed on the motherboard includes a first stripline and a second stripline that are disconnected from each other, the first stripline is configured to connect to a connection port of the signal adjustment component, and the second stripline is configured to connect to a radiating element of an antenna. In the first circuit state, the auxiliary stripline is connected to the first stripline and the second stripline, so that the radiating element connected to the second stripline participates in operation of the antenna, thereby increasing a quantity of operating radiating elements of the antenna. In the second circuit state, the auxiliary stripline is disconnected from the first stripline and/or the second stripline, so that the radiating element connected to the second stripline does not participate in operation of the antenna, thereby reducing the quantity of operating radiating elements of the antenna. The signal adjustment component in this solution may enable different quantities of radiating elements to participate in operation of the antenna, to adjust a beam width of the antenna. The switching component of the signal adjustment component can implement multi-level switching. Therefore, multi-level adjustment of the beam width of the antenna can be implemented, and application scenarios of the antenna can be enriched.

According to an exemplary embodiment, phase shifting of the antenna is performed by using the signal adjustment component. Specifically, the line is configured to connect to a radiating element of an antenna, one end of the auxiliary stripline is configured to connect to a connection port of the signal adjustment component, and the other end of the auxiliary stripline is in lap joint with the line. Specifically, the switching component may drive the auxiliary stripline to slide relative to the line, so that the auxiliary stripline is in lap joint with different locations of the line. In the first circuit state, the auxiliary stripline is in lap joint with a first connection point of the line; and in the second circuit state, the auxiliary stripline is in lap joint with a second connection point of the line. The driving component of the signal adjustment component drives the switching component to move, and adjusts a length of a transmission line between the radiating element and the connection port of the signal adjustment component, to implement multi-level phase shifting.

According to an exemplary embodiment, phase shifting of the antenna is also performed by using the signal adjustment component. Specifically, the line includes a third stripline and a fourth stripline that are disconnected from each other, the third stripline is configured to connect to a connection port of the signal adjustment component, and the fourth stripline is configured to connect to a radiating element of an antenna. One end of the auxiliary stripline is in lap joint with the third stripline, and the other end is in lap joint with the fourth stripline, so that the third stripline is electrically connected to the fourth stripline. The switching component may drive the one end of the auxiliary stripline to slide relative to the third stripline, and the other end to slide relative to the fourth stripline, so that the auxiliary stripline is in lap joint with different locations of the line. In the first circuit state, the auxiliary stripline is in lap joint with a third connection point of the third stripline, and the auxiliary stripline is in lap joint with a fourth connection point of the fourth stripline; and in the second circuit state, the auxiliary stripline is in lap joint with a fifth connection point of the third stripline, and the auxiliary stripline is in lap joint with a sixth connection point of the fourth stripline. The driving component of the signal adjustment component drives the switching component to move, and adjusts a length of a transmission line between the radiating element and the connection port of the signal adjustment component, to implement multi-level phase shifting.

According to an exemplary embodiment, phase shifting of the antenna is also performed by using the signal adjustment component. Specifically, one end of the line is configured to connect to a radiating element of an antenna, the other end is configured to connect to a connection port of the signal adjustment component, the line includes a preset line region, and two ends of the preset line region are respectively a first endpoint and a second endpoint. In the first circuit state, the auxiliary stripline is connected to the first endpoint and the second endpoint, so that the preset line region is short-circuited, and the auxiliary stripline is connected to the line; and in the second circuit state, the auxiliary stripline is disconnected from the first endpoint and/or the second endpoint, so that the auxiliary stripline is not connected to the line, and the preset line region is connected to the line. Multi-level phase shifting can be implemented by disposing the plurality of switching components.

According to an exemplary embodiment, a power division ratio of the antenna may be further adjusted by using the signal adjustment component. Specifically, the line includes a bus, a first stub, and a second stub, one end of the bus is configured to connect to a connection port of the signal adjustment component, the first stub and the second stub are connected in parallel and are connected to the other end of the bus, the first stub and the second stub are respectively configured to connect to different radiating elements of an antenna, and a cross-sectional area of the auxiliary stripline is greater than a cross-sectional area of the line. In the first circuit state, the auxiliary stripline covers a connection region between the bus and the first stub, and is connected to the line, to increase a power division ratio of the radiating element connected to the first stub. In the second circuit state, the auxiliary stripline is disconnected from the line, to reduce the power division ratio of the radiating element connected to the first stub. Multi-level phase shifting can be implemented by disposing the plurality of switching components.

According to an exemplary embodiment, the driving component may be further used as a dielectric plate to slide and implement phase shifting. Specifically, the line is configured to connect to the radiating element of the antenna. The driving component is a dielectric plate, the dielectric plate includes a phase shift part, and the phase shift part covers at least a part of the line; and the dielectric plate slides in the sliding direction to a third location and a fourth location, and a length of the line covered by the phase shift part at the third location is different from a length of the line covered by the phase shift part at the fourth location. Phase shifting of the radiating element can be implemented by moving the location of the dielectric plate, which is equivalent to implementing phase shifting by moving the location of the driving component. Therefore, this technical solution may be combined with the foregoing several technical solutions, to implement phase shifting while implementing functions such as beam adjustment or power division, to enrich the application scenarios of the antenna.

Specifically, in a process in which the dielectric plate (driving component) slides from the third location to the fourth location, the plurality of switching components is fastened to the first location or the second location. It may be understood that, in this solution, in a process in which the dielectric plate slides between the third location and the fourth location, the location of the switching component remains unchanged, so that performance of the antenna adjusted via the switching component remains unchanged.

According to an exemplary embodiment, another signal adjustment component is disclosed. The signal adjustment component includes a motherboard, a driving component, and a plurality of switching components. A line is disposed on the motherboard, and the line may be considered as an operating line of the signal adjustment component. Each switching component is movably assembled on the motherboard, and an auxiliary stripline is disposed on each switching component. Each switching component is configured to change a connection status with the line via the auxiliary stripline during motion. Specifically, the auxiliary stripline may be connected to or disconnected from the line. The driving component is slidably assembled on the motherboard, the driving component includes a plurality of driving parts, the plurality of driving parts one-to-one correspond to the plurality of switching components, and one driving part and one switching component that correspond to each other form a driving combination. Distances between switching components and driving parts in different driving combinations in a sliding direction are different, and in a sliding process of the driving component, as the driving component slides, different driving parts of the driving component drive the plurality of switching components to sequentially move, so that connection statuses between auxiliary striplines of the plurality of switching components and the line sequentially change, to implement multi-level switch adjustment of the signal adjustment component. In addition, when a connection status between an auxiliary stripline of one of the plurality of switching components and the line changes, a connection status between an auxiliary stripline of another switching component and the line remains unchanged. For example, when a disconnected state between an auxiliary stripline of the plurality of switching components and the line changes to a connected state, a connection status between an auxiliary stripline of another switching component and the line remains unchanged. According to an exemplary embodiment, one driving component drives different switching components to move, to implement multi-level switch adjustment, so that an antenna can present a large quantity of operating states, and is more flexibly used in a more complex signal coverage scenario, thereby meeting a customer's antenna requirements in multiple scenarios.

Specifically, for any switching component, an auxiliary stripline moves with the switching component; when the switching component is located at a first location, the auxiliary stripline and a line form a first circuit state; and when the switching component is located at a second location, the auxiliary stripline and the line form a second circuit state. The first location and the second location mainly indicate different locations of the switching component. The first circuit state is different from the second circuit state. The driving component is slidably assembled on the motherboard, and the driving component drives the switching component to be switched between the first location and the second location in a sliding process of the motherboard. Specifically, the driving component includes the plurality of driving parts, the plurality of driving parts one-to-one correspond to the plurality of switching components, the one driving part and the one switching component that correspond to each other are in driving connection to form the driving combination, and the driving part in the driving combination is configured to drive the switching component to move. Specifically, the driving part drives the switching component in the same driving combination to move to the corresponding first location or second location. The plurality of switching components is arranged in the sliding direction of the driving component, and the plurality of driving parts is also arranged in the sliding direction. When the driving component is located at a preset location, distances between switching components and driving parts in at least two driving combinations in the sliding direction are different. When the driving component slides to different locations in the sliding direction, switching components in different driving combinations are driven to move. According to an exemplary embodiment, the one driving component drives different switching components to move, to implement multi-level switch adjustment, so that the antenna can present the large quantity of operating states, and is more flexibly used in the more complex signal coverage scenario, thereby meeting the customer's antenna requirements in multiple scenarios.

According to an exemplary embodiment, the signal adjustment component includes a motherboard, a driving component, and a plurality of switching components. A plurality of lines is disposed on a surface of the motherboard. Each switching component is movably assembled on the motherboard, and an auxiliary stripline is disposed on each switching component. For any switching component, when the switching component is located at a first location, an auxiliary stripline and a line form a first circuit state; and when the switching component is located at a second location, the auxiliary stripline and the line form a second circuit state. The driving component is slidably assembled on the motherboard, the driving component includes a plurality of driving parts, one driving part is in driving connection to one switching component to form a driving combination, and the driving part in the driving combination drives the switching component to move to the corresponding first location or second location. The plurality of switching components is arranged in a sliding direction of the driving component, and the plurality of driving parts is also arranged in the sliding direction. When the driving component is located at a preset location, distances between switching components and driving parts in at least two driving combinations in the sliding direction are different. When the driving component slides to different locations in the sliding direction, switching components in different driving combinations are driven to move.

According to an exemplary embodiment, there may be a plurality of options for a translational switching component. For example, in a technical solution, the switching component includes a translational switching component, and the translational switching component moves in a preset plane without rotation. A plurality of sliding slots is disposed on the motherboard, and the translational switching component is slidably assembled in the sliding slot. For ease of description, it is considered that two ends of the sliding slot are respectively a first end and a second end. The driving part includes a first driving part. The first driving part is adapted to the translational switching component, and is configured to drive the translational switching component to move. The first driving part specifically includes a first oblique end surface and a second oblique end surface that are parallel to a first plane, and correspondingly, the translational switching component includes a third oblique end surface and a fourth oblique end surface that are parallel to the first plane. When the driving component slides to a first preset location in a first direction, the first oblique end surface abuts against the third oblique end surface, and the driving component continues to slide in the first direction, to drive the translational switching component to slide in the sliding slot in a direction from the first end to the second end until the auxiliary stripline and the line form the first circuit state. When the driving component slides to a second preset location in a second direction, the second oblique end surface abuts against the fourth oblique end surface, and the driving component continues to slide in the second direction, to drive the translational switching component to slide in the sliding slot in a direction from the second end to the first end until the auxiliary stripline and the line form the second circuit state. Specifically, the first direction and the second direction are parallel to the sliding direction, the first direction is opposite to the second direction, and the first plane intersects the sliding direction.

To implement multi-level driving of the switching component, when the driving component is located at the preset location, distances between first oblique end surfaces and third oblique end surfaces in the at least two driving combinations in the first direction are different.

To improve sliding stability of the switching component and facilitate stable maintenance of the first circuit state and the second circuit state, the first driving part includes a first limiting surface and a second limiting surface that are parallel to the sliding direction, and correspondingly, the translational switching component includes a third limiting surface and a fourth limiting surface that are arranged in the direction from the first end to the second end. When the translational switching component moves to a first location, the first limiting surface and the third limiting surface abut against each other in a third direction and are capable of sliding relative to each other in the sliding direction, where the third direction is perpendicular to the sliding direction. The first limiting surface abuts against the third limiting surface in the third direction, and the translational switching component is limited, so that the auxiliary stripline and the line stably remain in the first circuit state. When the driving component limits the translational switching component, the translational switching component does not affect sliding of the driving component, and the driving component may continue to slide, to drive another switching component to move. When the translational switching component moves to a second location, the second limiting surface and the fourth limiting surface abut against each other in the third direction and are capable of sliding relative to each other in the sliding direction. The second limiting surface abuts against the fourth limiting surface in the third direction, and the translational switching component is limited, so that the auxiliary stripline and the line stably remain in the second circuit state. When the driving component limits the translational switching component, the translational switching component does not affect sliding of the driving component, and the driving component may continue to slide, to drive another switching component to move.

To implement multi-level control of the plurality of switching components of the signal adjustment component, in the at least two driving combinations, lengths of first limiting surfaces of the driving parts in the sliding direction are different, and lengths of second limiting surfaces in the sliding direction are also different. In a process of driving different switching components to move, the driving component may slide relative to another switching component, to ensure multi-level control of the switching component of the signal adjustment component.

According to an exemplary embodiment, the switching component includes a rotating switching component, the rotating switching component is rotatably assembled on the motherboard via a rotating shaft, and the rotating switching component rotates under driving of the driving component. Specifically, the rotating switching component includes a first driving plane and a second driving plane that are parallel to an axial direction of the rotating shaft, the first driving plane and the second driving plane intersect at a preset angle, and the first driving plane and the second driving plane are sequentially arranged in the axial direction, that is, the first driving plane and the second driving plane are located in a two-layer structure that is of the rotating switching component and that is arranged in the axial direction. Correspondingly, the driving part includes a second driving part, the second driving part includes a first driving surface and a second driving surface, the first driving surface and the second driving surface are sequentially arranged in the axial direction, and the first driving surface and the second driving surface separately extend in a direction away from the rotating shaft. The first driving surface and the first driving plane are located at a same layer, and the second driving surface and the second driving plane are located at a same layer. When the driving component slides to a third preset location in the first direction, the first driving surface abuts against the first driving plane, the driving component continues to slide in the first direction, and the first driving surface drives the first driving plane to rotate, to further drive the rotating switching component to rotate by the preset angle in a first circumferential direction to the first location. When the driving component slides to a fourth preset location in the second direction, the second driving surface abuts against the second driving plane, the driving component continues to slide in the second direction, and the second driving surface drives the second driving plane to rotate, to further drive the rotating switching component to rotate by the preset angle in a second circumferential direction to the second location. If the first circumferential direction is opposite to the second circumferential direction, when the driving component slides in the first direction, the rotating switching component is driven to rotate in the first circumferential direction, and when the driving component slides in the second direction, the rotating switching component is driven to rotate in the second circumferential direction. In this case, when the driving component slides in an opposite direction, the rotating switching component rotates in the opposite direction.

To implement multi-level control of the plurality of switching components of the signal adjustment component, when the driving component is located at the preset location, distances between first driving surfaces and rotating shafts in the at least two driving combinations in the first direction are different. Therefore, when the driving component slides to different locations in the first direction or the second direction, different rotating switching components may be separately driven to rotate.

In a specific technical solution, the first driving surface and the second driving surface of the second driving part are axisymmetrically disposed, and a symmetry axis of the first driving surface and the second driving surface is parallel to the axial direction. Fitting between the second driving part and the rotating switching component in a case in which the driving component slides in the first direction is the same as that between the second driving part and the rotating switching component in a case in which the driving component slides in the second direction. This helps simplify a structure of the second driving part and a structure of the rotating switching component.

To improve sliding stability of the switching component and facilitate stable maintenance of the first circuit state and the second circuit state, the driving part includes a fifth limiting surface and a sixth limiting surface that are parallel to the sliding direction, and the fifth limiting surface and the sixth limiting surface are sequentially arranged in the axial direction. The fifth limiting surface and the first driving surface are located at a same layer, and the sixth limiting surface and the second driving surface are located at a same layer. When the rotating switching component rotates to the first location, the fifth limiting surface is parallel to and abuts against the first driving plane, so that the auxiliary stripline and the line stably remain in the first circuit state. When the rotating switching component rotates to the second location, the sixth limiting surface is parallel to and abuts against the second driving plane, so that the auxiliary stripline and the line stably remain in the second circuit state.

In According to an exemplary embodiment, the fifth limiting surface is connected to the first driving surface, and the first driving plane may continuously move between the fifth limiting surface and the first driving surface. The sixth limiting surface is connected to the second driving surface, and the second driving plane may continuously move between the sixth limiting surface and the second driving surface.

There is a plurality of options for the first driving surface and the second driving surface provided. For example, the first driving surface may be at least one of a plane, a paraboloid, or a semi-cylindrical surface. The second driving surface may be at least one of a plane, a paraboloid, or a semi-cylindrical surface. In conclusion, there is an included angle between the first driving surface and the fifth limiting surface, and there is an included angle between the second driving surface and the sixth limiting surface.

Because the rotating switching component rotates relative to the motherboard, the auxiliary stripline disposed on the rotating switching component is an arc-shaped auxiliary stripline, an area that is of the line and that corresponds to the rotating switching component includes an arc-shaped line, and the arc-shaped auxiliary stripline and the arc-shaped line form a first circuit state or a second circuit state. The arc-shaped auxiliary stripline rotates with rotation arc-shaped auxiliary stripline and the arc-shaped line.

The signal adjustment component provided in the foregoing technical solution may be used in different scenarios. In an application scenario, a beam of the antenna is adjusted by using the signal adjustment component. Specifically, one line disposed on the motherboard includes a first stripline and a second stripline that are disconnected from each other, the first stripline is configured to connect to a connection port of the signal adjustment component, and the second stripline is configured to connect to a radiating element of an antenna. In the first circuit state, the auxiliary stripline is connected to the first stripline and the second stripline, so that the radiating element connected to the second stripline participates in operation of the antenna, thereby increasing a quantity of operating radiating elements of the antenna. In the second circuit state, the auxiliary stripline is disconnected from the first stripline and/or the second stripline, so that the radiating element connected to the second stripline does not participate in operation of the antenna, thereby reducing the quantity of operating radiating elements of the antenna. The signal adjustment component in this solution may enable different quantities of radiating elements to participate in operation of the antenna, to adjust a beam width of the antenna. The switching component of the signal adjustment component can implement multi-level switching. Therefore, multi-level adjustment of the beam width of the antenna can be implemented, and application scenarios of the antenna can be enriched.

According to an exemplary embodiment, phase shifting of the antenna is performed by using the signal adjustment component. Specifically, the line is configured to connect to a radiating element of an antenna, one end of the auxiliary stripline is configured to connect to a connection port of the signal adjustment component, and the other end of the auxiliary stripline is in lap joint with the line. Specifically, the switching component may drive the auxiliary stripline to slide relative to the line, so that the auxiliary stripline is in lap joint with different locations of the line. In the first circuit state, the auxiliary stripline is in lap joint with a first connection point of the line; and in the second circuit state, the auxiliary stripline is in lap joint with a second connection point of the line. The driving component of the signal adjustment component drives the switching component to move, and adjusts a length of a transmission line between the radiating element and the connection port of the signal adjustment component, to implement multi-level phase shifting.

According to an exemplary embodiment, phase shifting of the antenna is also performed by using the signal adjustment component. Specifically, the line includes a third stripline and a fourth stripline that are disconnected from each other, the third stripline is configured to connect to a connection port of the signal adjustment component, and the fourth stripline is configured to connect to a radiating element of an antenna. One end of the auxiliary stripline is in lap joint with the third stripline, and the other end is in lap joint with the fourth stripline, so that the third stripline is electrically connected to the fourth stripline. The switching component may drive the one end of the auxiliary stripline to slide relative to the third stripline, and the other end to slide relative to the fourth stripline, so that the auxiliary stripline is in lap joint with different locations of the line. In the first circuit state, the auxiliary stripline is in lap joint with a third connection point of the third stripline, and the auxiliary stripline is in lap joint with a fourth connection point of the fourth stripline; and in the second circuit state, the auxiliary stripline is in lap joint with a fifth connection point of the third stripline, and the auxiliary stripline is in lap joint with a sixth connection point of the fourth stripline. The driving component of the signal adjustment component drives the switching component to move, and adjusts a length of a transmission line between the radiating element and the connection port of the signal adjustment component, to implement multi-level phase shifting.

According to an exemplary embodiment, phase shifting of the antenna is also performed by using the signal adjustment component. Specifically, one end of the line is configured to connect to a radiating element of an antenna, the other end is configured to connect to a connection port of the signal adjustment component, the line includes a preset line region, and two ends of the preset line region are respectively a first endpoint and a second endpoint. In the first circuit state, the auxiliary stripline is connected to the first endpoint and the second endpoint, so that the preset line region is short-circuited, and the auxiliary stripline is connected to the line; and in the second circuit state, the auxiliary stripline is disconnected from the first endpoint and/or the second endpoint, so that the auxiliary stripline is not connected to the line, and the preset line region is connected to the line. Multi-level phase shifting can be implemented by disposing the plurality of switching components.

According to an exemplary embodiment, a power division ratio of the antenna may be further adjusted by using the signal adjustment component. Specifically, the line includes a bus, a first stub, and a second stub, one end of the bus is configured to connect to a connection port of the signal adjustment component, the first stub and the second stub are connected in parallel and are connected to the other end of the bus, the first stub and the second stub are respectively configured to connect to different radiating elements of an antenna, and a cross-sectional area of the auxiliary stripline is greater than a cross-sectional area of the line. In the first circuit state, the auxiliary stripline covers a connection region between the bus and the first stub, and is connected to the line, to increase a power division ratio of the radiating element connected to the first stub. In the second circuit state, the auxiliary stripline is disconnected from the line, to reduce the power division ratio of the radiating element connected to the first stub. Multi-level phase shifting can be implemented by disposing the plurality of switching components.

According to an exemplary embodiment, the driving component may be further used as a dielectric plate to slide and implement phase shifting. Specifically, the line is configured to connect to the radiating element of the antenna. The driving component is a dielectric plate, the dielectric plate includes a phase shift part, and the phase shift part covers at least a part of the line; and the dielectric plate slides in the sliding direction to a third location and a fourth location, and a length of the line covered by the phase shift part at the third location is different from a length of the line covered by the phase shift part at the fourth location. Phase shifting of the radiating element can be implemented by moving the location of the dielectric plate, which is equivalent to implementing phase shifting by moving the location of the driving component. Therefore, this technical solution may be combined with the foregoing several technical solutions, to implement phase shifting while implementing functions such as beam adjustment or power division, to enrich the application scenarios of the antenna.

Specifically, in a process in which the dielectric plate (driving component) slides from the third location to the fourth location, the plurality of switching components is fastened to the first location or the second location. It may be understood that, in this solution, in a process in which the dielectric plate slides between the third location and the fourth location, the location of the switching component remains unchanged, so that performance of the antenna adjusted via the switching component remains unchanged.

According to an exemplary embodiment, an antenna is further disclosed. The antenna includes a radiating element and the signal adjustment component according to the first aspect. The radiating element is connected to a line of the signal adjustment component. The antenna can adjust an operating state of the antenna based on an actual scenario requirement, and the signal adjustment component can implement multi-level adjustment. This helps enrich application scenarios of the antenna.

According to an exemplary embodiment, a communication device is further disclosed. The communication device includes the antenna according to the second aspect, the communication device further includes a radio frequency processing circuit, and the antenna is connected to the radio frequency processing circuit. Specifically, the line of the signal adjustment component of the antenna is connected to the radio frequency processing circuit. The communication device may be used in a large quantity of scenarios, and the antenna does not need to be replaced. Therefore, it is convenient to change an application scenario, and costs are low.

### BRIEF DESCRIPTION OF DRAWINGS

Embodiments of the present disclosure will now be described by way of example only with reference to the accompanying drawings.

FIG. 1 is a diagram of a system architecture in accordance with an exemplary embodiment.

FIG. 2 is a diagram of a structure of a communication device according to an embodiment.

FIG. 3 is a diagram of a composition of an antenna according to an embodiment.

FIG. 4 is a diagram of a structure of a signal adjustment component according to an embodiment.

FIG. 5a is a diagram of an operating state of a signal adjustment component according to an embodiment.

FIG. 5b is a diagram of an operating state of a signal adjustment component according to an embodiment.

FIG. 5c is a diagram of an operating state of a signal adjustment component according to an embodiment.

FIG. 5d is a diagram of an operating state of a signal adjustment component according to an embodiment.

FIG. 6a is a diagram of an operating state of a signal adjustment component according to an embodiment.

FIG. 6b is a diagram of an operating state of a signal adjustment component according to an embodiment.

FIG. 7 is a diagram of an operating state of a signal adjustment component according to an embodiment.

FIG. 8 is a diagram of an operating state of a signal adjustment component according to an embodiment.

FIG. 9a is a diagram of an operating state of a signal adjustment component according to an embodiment.

FIG. 9b is a diagram of an operating state of a signal adjustment component according to an embodiment.

FIG. 9c is a diagram of an operating state of a signal adjustment component according to an embodiment.

FIG. 9d is a diagram of an operating state of a signal adjustment component according to an embodiment.

FIG. 10 is a diagram of a partially enlarged structure of a signal adjustment component according to an embodiment.

FIG. 11a is a diagram of a partial structure of a signal adjustment component according to an embodiment.

FIG. 11b is a diagram of a partially exploded structure of a signal adjustment component according to an embodiment.

FIG. 12 is a partially enlarged diagram of a signal adjustment component according to an embodiment.

FIG. 13 is a diagram of several possible structures of a sliding slot of a base according to an embodiment.

FIG. 14a is a diagram of a motion process of a translational switching component of a signal adjustment component according to an embodiment.

FIG. 14b is a diagram of a motion process of a translational switching component of a signal adjustment component according to an embodiment.

FIG. 14c is a diagram of a motion process of a translational switching component of a signal adjustment component according to an embodiment.

FIG. 14d is a diagram of a motion process of a translational switching component of a signal adjustment component according to an embodiment of this application;

FIG. 14e is a diagram of a motion process of a translational switching component of a signal adjustment component according to an embodiment.

FIG. 15a is a diagram of a motion process of a translational switching component of a signal adjustment component according to an embodiment.

FIG. 15b is a diagram of a motion process of a translational switching component of a signal adjustment component according to an embodiment.

FIG. 15c is a diagram of a motion process of a translational switching component of a signal adjustment component according to an embodiment.

FIG. 15d is a diagram of a motion process of a translational switching component of a signal adjustment component according to an embodiment.

FIG. 16a is a diagram of a partial structure of a signal adjustment component according to an embodiment.

FIG. 16b is a diagram of a partially exploded structure of a signal adjustment component according to an embodiment.

FIG. 17a is a diagram of a structure of a rotating switching component according to an embodiment.

FIG. 17b is a diagram of a structure of a rotating switching component according to an embodiment.

FIG. 18 is a diagram of a structure of a driving part of a driving component according to an embodiment.

FIG. 19a is a diagram of a motion process of a rotating switching component of a signal adjustment component according to an embodiment.

FIG. 19b is a diagram of a motion process of a rotating switching component of a signal adjustment component according to an embodiment.

FIG. 19c is a diagram of a motion process of a rotating switching component of a signal adjustment component according to an embodiment.

FIG. 19d is a diagram of a motion process of a rotating switching component of a signal adjustment component according to an embodiment.

FIG. 19e is a diagram of a motion process of a rotating switching component of a signal adjustment component according to an embodiment.

FIG. 20a is a diagram of a motion process of a rotating switching component of a signal adjustment component according to an embodiment.

FIG. 20b is a diagram of a motion process of a rotating switching component of a signal adjustment component according to an embodiment.

FIG. 20c is a diagram of a motion process of a rotating switching component of a signal adjustment component according to an embodiment.

FIG. 20d is a diagram of a motion process of a rotating switching component of a signal adjustment component according to an embodiment.

FIG. 21a is a diagram of a motion process of a signal adjustment component according to an embodiment.

FIG. 21b is a diagram of a motion process of a signal adjustment component according to an embodiment.

FIG. 21c is a diagram of a motion process of a signal adjustment component according to an embodiment.

### DESCRIPTION OF EMBODIMENTS

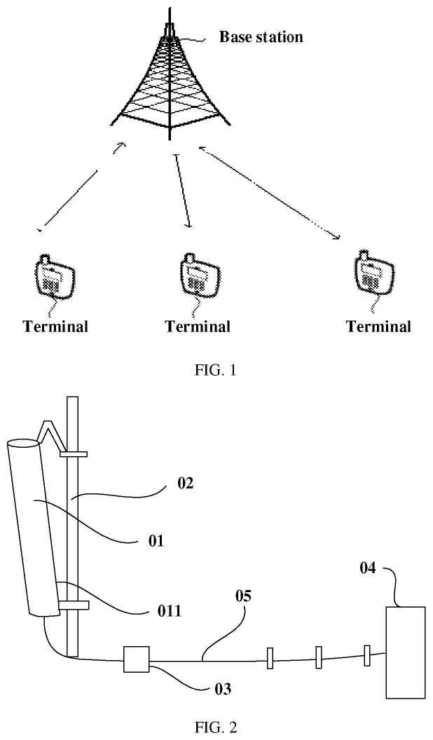

To facilitate understanding of a signal adjustment component, an antenna, and a communication device provided in embodiments of the disclosure, the following describes an application scenario of the signal adjustment component, the antenna, and the communication device. FIG. 1 is a diagram of a system architecture to which embodiments of the disclosure are applicable. As shown in FIG. 1, the application scenario may include a base station and terminals. Wireless communication can be implemented between the base station and the terminal. The base station may also be referred to as an access network device, and may be located in a base station subsystem (BSS), a terrestrial radio access network (UMTS terrestrial radio access network, UTRAN), or an evolved terrestrial radio access network (E-UTRAN), and is configured to perform cell coverage of a signal to implement communication between a terminal device and a wireless network. Specifically, the base station may be a base transceiver station (BTS) in a global system for mobile communications (GSM) or a code division multiple access (CDMA) system, may be a NodeB (NB) in a wideband code division multiple access (WCDMA) system, may be an evolved NodeB (eNB, or eNodeB) in a long term evolution (LTE) system, or may be a radio controller in a cloud radio access network (CRAN) scenario. Alternatively, the base station may be a relay station, an access point, a vehicle-mounted device, a wearable device, a gNodeB (gNodeB or gNB) in a new radio (NR) system, an access network device in a future evolved network, or the like. This is not limited to the embodiments of the disclosure.

The base station is equipped with an antenna to implement signal transmission in space. FIG. 2 is a diagram of a possible structure of a communication device according to an embodiment of this application. As shown in FIG. 2, the communication device may be specifically a base station, and the base station may usually include structures such as an antenna 01 and a mounting support 02. The antenna 01 is mounted on the mounting support 02, to receive or transmit a signal of the antenna 01. Specifically, the mounting support 02 may be a pole, a tower, or the like. FIG. 2 shows only an example of components that may be included in the base station and a location relationship between the components. In other embodiments, the base station may further include other components, or a location relationship between the components is different from that shown in FIG. 2.

In addition, the base station may further include a remote radio unit 03 and a baseband processing unit 04. As shown in FIG. 2, the baseband processing unit 04 may be connected to the antenna 01 via the remote radio unit 03. The baseband processing unit 04 may be connected to a feed network of the antenna 01 via the remote radio unit 03. In some implementations, the remote radio unit 03 may also be referred to as a remote radio unit (RRU), and the baseband processing unit 04 may also be referred to as a baseband unit (BBU).

In an exemplary embodiment, as shown in FIG. 2, the remote radio unit 03 and the baseband processing unit 04 may both be located at a remote end of the antenna 01. The remote radio unit 03 and the baseband processing unit 04 may be connected through a cable 05. It should be noted that FIG. 2 shows only an example of a location relationship between the remote radio unit 03 and the antenna 01.

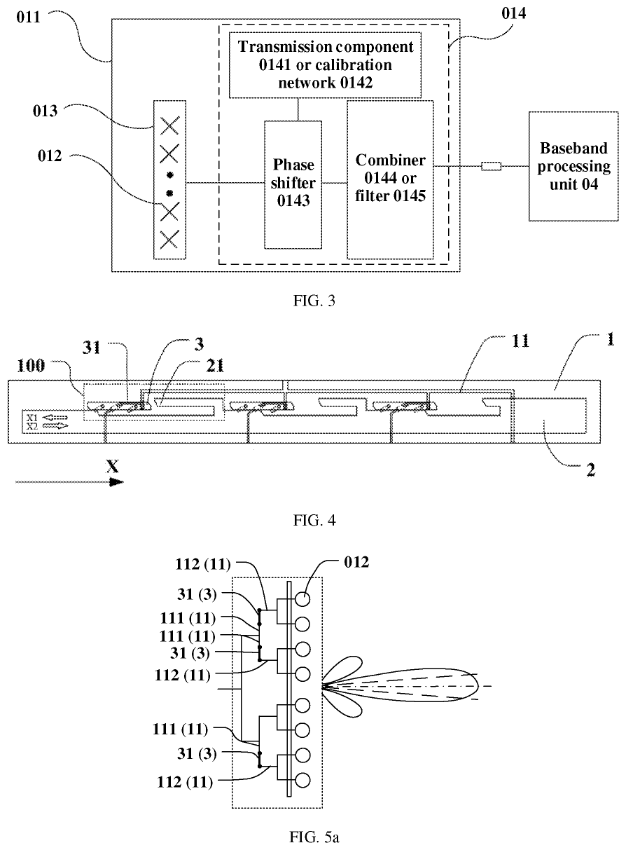

More specifically, referring to FIG. 2 and FIG. 3, a diagram of composition of the antenna according to an exemplary embodiment are illustrated. As shown in FIG. 3, the antenna 01 may include a radome 011, a radiating element 012, a reflection plate 013, and a feed network 014. The radome 011 has a good electromagnetic wave penetration characteristic in terms of electrical properties and can withstand impact of an external harsh environment in terms of mechanical performance, thereby protecting the antenna 01 from being affected by the external environment. The radiating element 012 may also be referred to as an antenna element, an oscillator, or the like, and can effectively send or receive an antenna signal. For the antenna 01, frequencies of different radiating elements 012 may be the same or different. The reflection plate 013 may also be referred to as a motherboard, an antenna panel, a reflective surface, or the like, and may be made of metal. When the antenna 01 receives a signal, the reflection plate 013 may reflect and aggregate the signal of the antenna 01 at a reception point. The radiating element 012 is usually placed on one side of the reflection plate 013. In this way, a signal receiving or transmitting capability of the antenna 01 can be greatly enhanced, and an interference signal from a back side of the reflection plate 013 (where the back side of the reflection plate 013 is a side away from a side that is of the reflection plate 013 and on which the radiating element 012 is disposed) can be blocked and shielded.

Moreover, in a base station, the radiating element 012 is connected to the feed network 014. The feed network 014 is usually formed by a controlled impedance transmission line. The feed network 014 may feed a signal to the radiating element 012 based on a specific amplitude and phase, or send a received signal to the baseband processing unit 04 of the base station based on a specific amplitude and phase. Specifically, in some implementations, the feed network 014 may implement different radiation beam directions via a transmission component 0141, or may be connected to a calibration network 0142 to obtain a calibration signal required by the system. The feed network 014 may include a phase shifter 0143, configured to change a maximum direction of antenna signal radiation. Some modules for performance extension may be further disposed in the feed network 014. For example, a combiner 0144 may be configured to: combine signals of different frequencies into one signal and transmit the signal via the radiating element 012; or during reverse use, may be configured to: divide, based on different frequencies, signals received by the radiating element 012 into a plurality of signals and transmit the signals to the baseband processing unit 04 for processing. For another example, a filter 0145 is configured to filter out an interference signal.

Furthermore, the feed network 014 is disposed on the signal adjustment component, so that the feed network 014 can be adjusted via the signal adjustment component. The signal adjustment component in embodiments of the disclosure includes a line, and the line may be specifically the feed network. The signal adjustment component includes a connection port, and the connection port is connected to a line of the signal adjustment component. The communication device includes a radio frequency processing circuit, and the radio frequency processing circuit may be specifically located in the radio remote unit 03. The connection port of the signal adjustment component is connected to the radio frequency processing circuit, so that the line of the signal adjustment component is connected to the radio frequency processing circuit.

FIG. 4 is a diagram of a structure of a signal adjustment component according to an embodiment of the disclosure. As shown in FIG. 4, the signal adjustment component provided in this application includes a motherboard 1, a driving component 2, and a plurality of switching components 3. A line 11 is disposed on a surface of the motherboard 1. One end of the line 11 is configured to connect to a radiating element of an antenna, and the other end is configured to connect to a connection port of the signal adjustment component. The line 11 is a general term, and may be understood as all lines located on the surface of the motherboard 1. For example, the line 11 may include a plurality of parts or a plurality of branches, and the plurality of parts of the plurality of lines 11 may be connected, disconnected, connected in series, connected in parallel, or the like. The motherboard 1 may be a printed circuit board (PCB), and the line 11 may be a copper trace on the PCB board. Each switching component 3 is movably assembled on the motherboard 1, and an auxiliary stripline 31 is disposed on each switching component 3. Each switching component 3 is configured to change a connection status with the line 11 via the auxiliary stripline 31 during motion. Specifically, the auxiliary stripline 31 may be connected to and disconnected from the line 11 when the switching component 3 is at different locations. The driving component 2 is slidably assembled on the motherboard 1, the driving component 2 includes a plurality of driving parts 21, the plurality of driving parts 21 one-to-one correspond to the plurality of switching components 3, and one driving part 21 and one switching component 3 that correspond to each other form a driving combination 100. The driving part 21 in the driving combination 100 is configured to drive the switching component 3 to move. Distances between switching components 3 and driving parts 21 in different driving combinations 100 in a sliding direction are different, and in a sliding process of the driving component 2, as the driving component 2 slides, different driving parts 21 of the driving component 2 drive the plurality of switching components 3 to sequentially move, so that connection statuses between auxiliary striplines 31 of the plurality of switching components 3 and the line 11 sequentially change, to implement multi-level switch adjustment of the signal adjustment component. In addition, when a connection status between an auxiliary stripline 31 of one of the plurality of switching components 3 and the line 11 changes, a connection status between an auxiliary stripline 31 of another switching component 3 and the line 11 remains unchanged. For example, as the driving component 2 moves, the driving parts 21 are sequentially in contact with the corresponding switching components 3 and drive the switching components 3 to move, so that auxiliary striplines 31 of the plurality of switching components 3 are sequentially connected to the line 11. When an auxiliary stripline 31 of one of the switching components 3 is connected to the line 11, a connection status between an auxiliary stripline 31 of another switching component 3 and the line 11 remains unchanged. According to an exemplary embodiment, one driving component 2 drives different switching components 3 to move, to implement multi-level switch adjustment, so that the antenna can present a large quantity of operating states, and is more flexibly used in a more complex signal coverage scenario, thereby meeting a customer's antenna requirements in multiple scenarios.

According to an exemplary embodiment, each switching component 3 is configured to change a connection status with the line 11 via the auxiliary stripline 31 during motion. Specifically, each switching component 3 is at least at a first location and a second location during motion of the motherboard 1, or each switching component 3 is switched between at least the first location and the second location. It should be noted that each switching component 3 has a first location and a second location that correspond to the switching component 3. In other words, the first location and the second location are not two locations set on the motherboard 1, but are relative to each switching component 3, and are equivalent to locations of the switching component 3 in two states. For one switching component 3 in the signal adjustment component, an auxiliary stripline 31 on the switching component 3 moves with the switching component 3. When the switching component 3 is located at the first location, the auxiliary stripline 31 and the line 11 form a first circuit state; and when the switching component 3 is located at the second location, the auxiliary stripline 31 and the line 11 form a second circuit state. The first circuit state is different from the second circuit state.

In an embodiment, the driving component 2 is slidably assembled on the motherboard 1. The driving component 2 specifically includes the plurality of driving parts 21, and the one driving part 21 and the one switching component 3 that correspond to each other form the driving combination 100. In a specific embodiment, the plurality of driving parts 21 of the signal adjustment component may be disposed in a one-to-one correspondence with the plurality of switching components 3. That a driving part 21 in one driving combination 100 drives a switching component 3 to move may specifically be driving the switching component 3 to move to a corresponding first location or second location. Specifically, the plurality of switching components 3 is arranged in a sliding direction X of the driving component 2, and the plurality of driving parts 21 is also arranged in the sliding direction X. When the driving component 2 is located at a preset location, distances between switching components 3 and driving parts 21 in at least two driving combinations 100 in the sliding direction X are different; and when the driving component 2 slides to different locations in the sliding direction X, switching components 3 in different driving combinations 100 are driven to move, so that different auxiliary striplines 31 and the line 11 are switched between the first circuit state and the second circuit state. In this embodiment, the one driving component 2 drives different switching components 3 to move, to implement multi-level switch adjustment, so that the antenna can present the large quantity of operating states, and is more flexibly used in the more complex signal coverage scenario, thereby meeting the customer's antenna requirements in multiple scenarios.

Specifically, the sliding direction of the driving component 2 includes a first direction X1 and a second direction X2. The first direction X1 and the second direction X2 are parallel to the sliding direction, and the first direction X1 is opposite to the second direction X2.

The preset location may be any location at which the driving component 2 is located, so that the distance between the switching component 3 and the driving part 21 in the sliding direction is determined when the driving component 2 remains fixed at the preset location. For ease of understanding, the preset location may be defined as a start location at which the driving component 2 moves in a direction, to be specific, in an opposite direction, the driving component 2 cannot slide, and can slide only in the direction. For example, in one case, it is considered that the preset location is a start location at which the driving component 2 slides in the first direction X1. In this case, the driving component 2 cannot slide in the second direction X2 (for example, the driving component 2 is limited by a limiting structure, or the driving component 2 interferes with another structure). In another case, the preset location may be a start location at which the driving component 2 slides in the second direction X2. In this case, the driving component 2 cannot slide in the second direction X2 (for example, the driving component 2 is limited by a limiting structure, or the driving component 2 interferes with another structure).

In an embodiment, the driving combination 100 includes a first driving combination and a second driving combination. In the first driving combination, a distance between an edge that is of a driving part 21 and that faces a switching component 3 and an edge that is of the switching component 3 and that faces the driving part 21 in the first direction X1 is a first distance. In the second driving combination, a distance between an edge that is of a driving part 21 and that faces a switching component 3 and an edge that is of the switching component 3 and that faces the driving part 21 in the first direction X1 is a second distance. The first distance is different from the second distance.

In the first driving combination 100, a distance between the edge that is of the driving part 21 and that faces the switching component 3 and the edge that is of the switching component 3 and that faces the driving part 21 in the second direction X2 is a third distance. In the second driving combination 100, a distance between the edge that is of the driving part 21 and that faces the switching component 3 and the edge that is of the switching component 3 and that faces the driving part 21 in the second direction X2 is a fourth distance. The third distance is different from the fourth distance.

The edge that is of the driving part 21 and that faces the switching component 3 and the edge that is of the switching component 3 and that faces the driving part 21 are respectively edges that can generate a driving relationship, and are two edges that fit each other. For example, in the first direction X1, when the edge that is of the driving part 21 and that faces the switching component 3 is in contact with the edge that is of the switching component 3 and that faces the driving part 21, the driving part 21 continues to slide in the first direction X1, and starts to drive the switching component 3 to move. Similarly, in the second direction X2, when the edge that is of the driving part 21 and that faces the switching component 3 is in contact with the edge that is of the switching component 3 and that faces the driving part 21, the driving part 21 continues to slide in the second direction X2, and starts to drive the switching component 3 to move.

In an embodiment, driving distances between driving parts 21 and switching components 3 in different driving combinations 100 are different. The driving distance means that after the driving component 2 slides for a specific distance in a direction from a preset location, the driving part 21 starts to drive the switching component 3 to move. In this case, the “specific distance” of sliding is the driving distance. For ease of understanding, the preset location may be defined as a start location at which the driving component 2 moves in a direction, to be specific, in an opposite direction, the driving component 2 cannot slide, and can slide only in the direction. The driving component 2 starts to slide from the start location. After the driving component 2 slides by one distance, a driving part 21 in a driving combination 100 starts to drive a corresponding switching component 3 to move. The driving component 2 continues to slide, and after the driving component 2 slides by another distance, a driving part 21 in another driving combination 100 starts to drive a corresponding switching component 3 to move. The same rule applies to the rest. The “one distance” is a distance by which the driving component 2 slides from the start location to this location when the driving part 21 in the one driving combination 100 starts to drive the corresponding switching component 3 to move. The distance may be understood as a driving distance corresponding to the one driving combination 100. The “another distance” is a distance by which the driving component 2 slides from the start location to this location when the driving part 21 in the another driving combination 100 starts to drive the corresponding switching component 3 to move. The distance may be understood as a driving distance corresponding to the another driving combination 100.

When the driving component 2 slides in the first direction X1, the driving distances between the driving parts 21 and the switching components 3 in different driving combinations 100 are different; and when the driving component 2 slides in the second direction X2, the driving distances between the driving parts 21 and the switching components 3 in different driving combinations 100 are also different.

According to an exemplary embodiment, the driving distances between the driving parts 21 and the switching components 3 in different driving combinations 100 are different, so that in a process in which the driving component 2 slides in any direction, connection statuses between the switching components 3 in different driving combinations 100 and the line 11 sequentially change. In addition, when a connection status between an auxiliary stripline 31 of a switching component 3 in one driving combination 100 and the line 11 changes, a connection status between an auxiliary stripline 31 of a switching component 3 in another driving combination 100 and the line 11 remains unchanged.

Moreover, simple linear motion of the driving component 2 is used to control the switching component 3 to drive motion and positioning of the auxiliary stripline 31, to change a status of each branch (the line 11 corresponding to one switching component 3) of a feed network of the antenna. The plurality of switching components 3 is used in parallel, so that multi-level status switching can be implemented. Multi-level status switching means that under the linear motion of the same driving component 2, statuses of branches can change in a specific sequence in the plurality of driving combinations 100. Switching components 3 at a same level are switching components 3 that are synchronously switched, switching components 3 at different levels are switching components 3 in a sequence in terms of time, and switching of the switching components 3 at different levels does not interfere with each other.

In an exemplary embodiment, the driving component 2 is slidably assembled on the motherboard 1 in a plurality of manners. In a possible embodiment, the driving component 2 may be assembled on the motherboard 1 via gears and racks, and is driven via a motor. In a possible embodiment, the driving component 2 may be slidably assembled on the motherboard 1 via a hydraulic pump, an air pressure pump, or the like.

In an exemplary embodiment, the signal adjustment component may be specifically a radio frequency apparatus. The following lists several possible specific structures and corresponding application scenarios of the signal adjustment component provided in the disclosure when the signal adjustment component is used as the radio frequency apparatus.

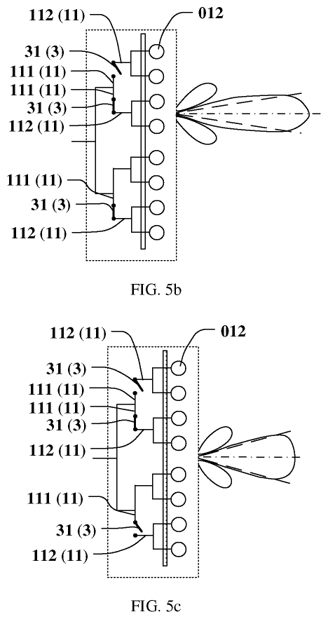

In an exemplary embodiment, beam adjustment of the antenna is implemented by using the signal adjustment component. FIG. 5a to FIG. 5d are diagrams of different operating states of the signal adjustment component according to embodiments of the disclosure. In this embodiment, one line 11 includes a first stripline 111 and a second stripline 112 that are disconnected from each other, the first stripline 111 is configured to connect to the connection port of the signal adjustment component, and the second stripline 112 is configured to connect to the radiating element of the antenna. In the first circuit state, the auxiliary stripline 31 of the switching component 3 is connected to the first stripline 111 and the second stripline 112, so that the radiating element connected to the second stripline 112 is connected to the connection port of the signal adjustment component, and participates in operation of the antenna to radiate a signal. In the second circuit state, the auxiliary stripline 31 of the switching component 3 is disconnected from the first stripline 111 and/or the second stripline 112, so that the first stripline 111 and the second stripline 112 of the line 11 are disconnected, and the radiating element connected to the second stripline 112 is disconnected from the connection port of the signal adjustment component, and does not participate in operation of the antenna and further, does not radiate a signal. The switching component 3 is used to drive the auxiliary stripline 31 to move, so that different quantities of radiating elements can participate in operation of the antenna, to adjust a beam width of the antenna.

Specifically, the antenna performs signal coverage through a beam. When input power of the antenna is fixed, a larger quantity of radiating elements at an output end of the antenna indicates a narrower beam, a higher gain, and a more centralized energy radiation range. This is conducive to long-distance and small-range signal coverage. A smaller quantity of radiating elements at the output end of the antenna indicates a wider beam, a lower gain, and a more dispersed energy radiation range. This is conducive to short-distance and large-range signal coverage. In this solution, the driving component 2 drives different switching components 3 to move, so that different quantities of radiating elements can participate in operation of the antenna, thereby implementing width conversion of a vertical beam of the antenna, and implementing multi-level beam adjustment.

In the embodiments shown in FIG. 5a to FIG. 5d, the antenna includes eight radiating elements and three switching components 3. Every two radiating elements form a group and are connected to the connection port of the signal adjustment component, and there are four groups of radiating elements in total. One group of radiating elements in the four groups of radiating elements is directly connected to the signal adjustment component, and the other three groups of radiating elements are separately connected to the connection port of the signal adjustment component via the switching components 3. Specifically, every two radiating elements are connected to one second stripline 112. As shown in FIG. 5a, in an operating state, the three switching components 3 all enable corresponding auxiliary striplines 31 and the line 11 to be in the first circuit state, and the eight radiating elements all participate in operation of the antenna to radiate signals. In the operating state, the antenna has a highest gain, most concentrated energy, a narrowest beam (for example, a beam width may be 9°), and a smallest antenna signal coverage angle but a largest coverage distance. As shown in FIG. 5b, in an operating state, two switching components 3 enable corresponding auxiliary striplines 31 and the line 11 to be in the first circuit state, and one switching component 3 enables a corresponding auxiliary stripline 31 and the line 11 to be in the second circuit state. Six radiating elements participate in operation of the antenna, and two radiating elements do not participate in operation of the antenna. Compared with the operating state in the embodiment shown in FIG. 5a, in the operating state, the gain of the antenna is reduced, and the beam is widened (for example, a beam width may be 12°). As shown in FIG. 5c, in an operating state, one switching component 3 enables a corresponding auxiliary stripline 31 and the line 11 to be in the first circuit state, and two switching components 3 enable corresponding auxiliary striplines 31 and the line 11 to be in the second circuit state. Four radiating elements participate in operation of the antenna, and four radiating elements do not participate in operation of the antenna. In the operating state, energy radiation is diffused in a direction, and the beam is widened (for example, a beam width may be 15°). As shown in FIG. 5d, in an operating state, three switching components 3 all enable corresponding auxiliary striplines 31 and the line 11 to be in the second circuit state. Two radiating elements participate in operation of the antenna, and six radiating elements do not participate in operation of the antenna. In the operating state, the antenna has a lowest gain, most divergent energy, a widest beam (for example, a beam width may be 30°), and a largest signal coverage angle but a smallest coverage distance.

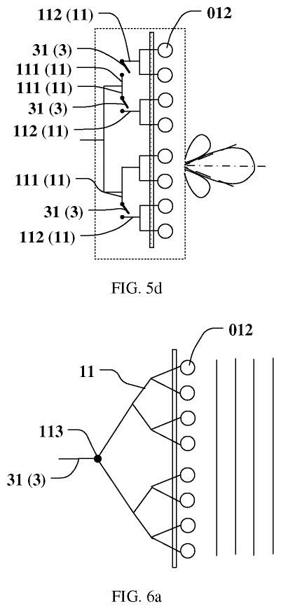

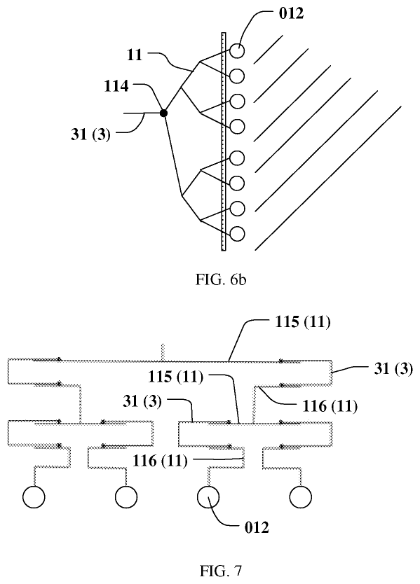

In an exemplary embodiment, phase shifting of the antenna is implemented by using the signal adjustment component. FIG. 6a and FIG. 6b are diagrams of different operating states of the signal adjustment component according to embodiments of the disclosure. In this embodiment, the line 11 is configured to connect to the radiating element of the antenna, one end of the auxiliary stripline 31 is in lap joint with the line 11, and the other end is configured to connect to the connection port of the signal adjustment component. The driving component 2 drives the switching component 3 to drive the auxiliary stripline 31 to move, so that the auxiliary stripline 31 is in lap joint with different locations of the line 11. In the first circuit state, the auxiliary stripline 31 is in lap joint with a first connection point 113 of the line 11. In the second circuit state, the auxiliary stripline 31 is in lap joint with a second connection point 114 of the line 11. As shown in FIG. 6a, in one operating state, the antenna has no electrical downtilt. As shown in FIG. 6b, in the other operating state, the antenna has an electrical downtilt. In this solution, the driving component 2 of the signal adjustment component drives the switching component 3 to move, to adjust a length of a transmission line between the radiating element and the connection port of the signal adjustment component, to implement phase shifting. In this solution, multi-level phase shifting of the antenna can be implemented by using the signal adjustment component.

In a third embodiment, phase shifting of the antenna is also implemented by using the signal adjustment component. FIG. 7 is a diagram of an operating state of the signal adjustment component according to an embodiment of the disclosure. In this embodiment, the line 11 includes a third stripline 115 and a fourth stripline 116 that are disconnected from each other, the third stripline 115 is configured to connect to the connection port of the signal adjustment component, and the fourth stripline 116 is configured to connect to the radiating element of the antenna; and one end of the auxiliary stripline 31 is in lap joint with the third stripline 115, and the other end is in lap joint with the fourth stripline 116, so that the third stripline 115 is electrically connected to the fourth stripline 116. In the first circuit state, the auxiliary stripline 31 is in lap joint with a third connection point of the third stripline 115, and the auxiliary stripline 31 is in lap joint with a fourth connection point of the fourth stripline 116; and in the second circuit state, the auxiliary stripline 31 is in lap joint with a fifth connection point of the third stripline 115, and the auxiliary stripline 31 is in lap joint with a sixth connection point of the fourth stripline 116. In this solution, the switching component 3 drives the auxiliary stripline 31 to slide, to adjust a connection location between the auxiliary stripline 31 and the third stripline 115 and a connection location between the auxiliary stripline 31 and the fourth stripline 116, and further to adjust the length of the transmission line between the radiating element and the connection port of the signal adjustment component, thereby implementing phase shifting. In this solution, phase shifting of the signal adjustment component can be implemented.

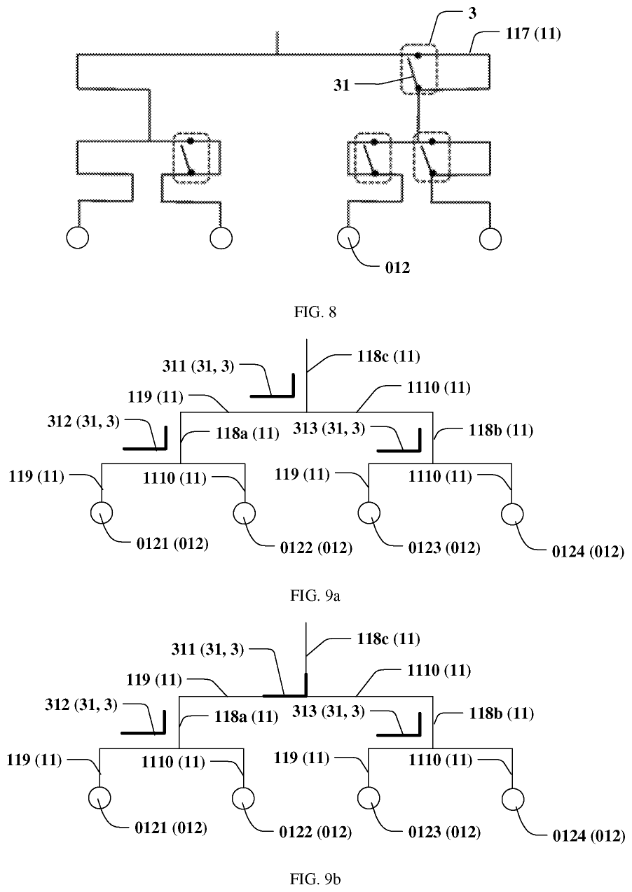

In an exemplary embodiment, phase shifting of the antenna is also implemented by using the signal adjustment component. FIG. 8 is a diagram of an operating state of the signal adjustment component according to an embodiment of the disclosure. In this embodiment, one end of the line 11 is configured to connect to the radiating element of the antenna, and the other end is configured to connect to the connection port of the signal adjustment component. The line 11 includes a preset line region 117, and two ends of the preset line region 117 are respectively a first endpoint and a second endpoint. In the first circuit state, the auxiliary stripline 31 is connected to the first endpoint and the second endpoint, so that the preset line region 117 is short-circuited and is not connected to the line 11, and the auxiliary stripline 31 is connected to the line 11. In the second circuit state, the auxiliary stripline 31 is disconnected from the first endpoint and/or the second endpoint, so that the auxiliary stripline 31 is not connected to the line 11, and the preset line region 117 is connected to the line 11. If a length of the preset line region 117 is different from a length of the auxiliary stripline 31, a line length connected to the line in the first circuit state is different from a line length connected to the line in the second circuit state, so that line lengths of the radiating element and the connection port are different. Therefore, in this solution, phase shifting can also be implemented. Multi-level phase shifting can be implemented by disposing the plurality of switching components 3.

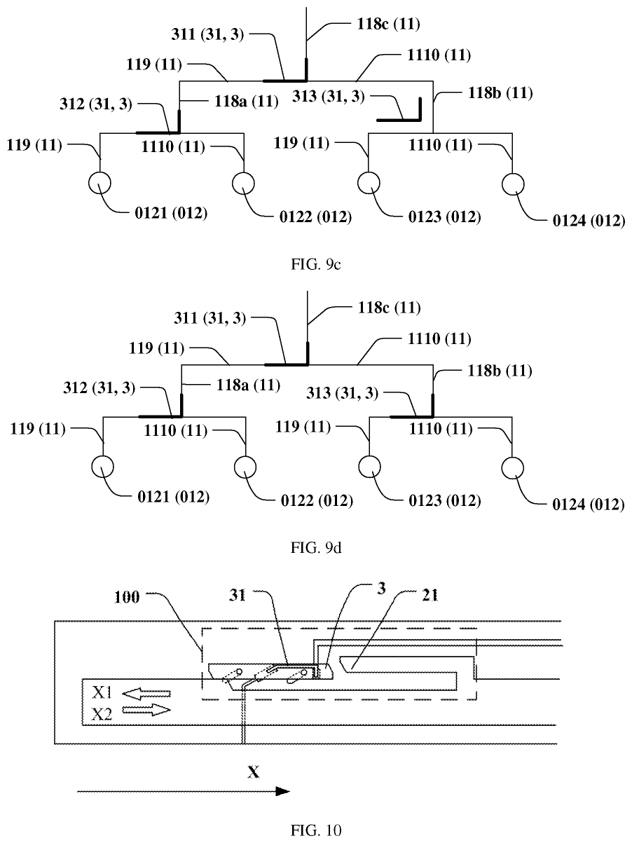

In an exemplary embodiment, a power division ratio of the antenna is adjusted by using the signal adjustment component. FIG. 9a to FIG. 9d are diagrams of different operating states of the signal adjustment component according to embodiments of the disclosure. In this embodiment, the line 11 includes a bus 118, a first stub 119, and a second stub 1110, one end of the bus 118 is configured to connect to the connection port of the signal adjustment component, and the first stub 119 and the second stub 1110 are connected in parallel and are connected to the other end of the bus 118. The first stub 119 and the second stub 1110 are respectively configured to connect to different radiating elements of the antenna, and a cross-sectional area of the auxiliary stripline 31 is greater than a cross-sectional area of the line 11. In an embodiment, both the auxiliary stripline 31 and the line 11 are striplines, and thicknesses of the striplines are the same. In this case, a line width of the auxiliary stripline 31 is greater than a line width of the line 11. In the first circuit state, the auxiliary stripline 31 covers a connection region between the bus 118 and the first stub, and is connected to the line 11, to increase a power division ratio of the radiating element connected to the first stub; and in the second circuit state, the auxiliary stripline 31 is disconnected from the line 11, to reduce the power division ratio of the radiating element connected to the first stub. The bus 118, the first stub 119, and the second stub 1110 correspond to three parts of one switching component 3.

In the embodiment shown in FIG. 9a to FIG. 9d, the signal adjustment component is configured to connect to a first radiating element 0121, a second radiating element 0122, a third radiating element 0123, and a fourth radiating element 0124, and the signal adjustment component includes three switching components 3. Each switching component 3 has one auxiliary stripline 31, and the auxiliary stripline 31 of the signal adjustment component includes a first auxiliary stripline 311, a second auxiliary stripline 312, and a third auxiliary stripline 313. A first stub 119 corresponding to one of the switching components 3 is connected to the first radiating element 0121, a second stub 1110 is connected to the second radiating element 0122, and the first stub 119 and the second stub 1110 are connected to a first bus 118a. A first stub 119 corresponding to another of the switching components 3 is connected to the third radiating element 0123, a second stub 1110 is connected to the fourth radiating element 0124, and the first stub 119 and the second stub 1110 are connected to a second bus 118b. The first bus 118a and the second bus 118b are used as a first stub 119 and a second stub 1110 of another switching component 3, and the first bus 118a and the second bus 118b are connected to a third bus 118c. As shown in FIG. 9a, in an operating state, none of the three auxiliary striplines 31 is connected to the line 11, and power division of the four radiating elements is 1:1:1:1. As shown in FIG. 9b, in an operating state, the first auxiliary stripline 311 covers a connection region between the third bus 118c and the first bus 118a, the other two auxiliary striplines 31 are not connected to the line 11, and the power division of the four radiating elements is 2:2:1:1. As shown in FIG. 9c, in an operating state, the first auxiliary stripline 311 covers the connection region between the third bus 118c and the first bus 118a, the second auxiliary stripline 312 covers a connection region between the first bus 118a and the first stub 119, the third auxiliary stripline 313 is not connected to the line 11, and the power division of the four radiating elements is 8:4:3:3. As shown in FIG. 9d, in an operating state, the first auxiliary stripline 311 covers the connection region between the third bus 118c and the first bus 118a, the second auxiliary stripline 312 covers the connection region between the first bus 118a and the first stub 119, the third auxiliary stripline 313 covers a connection region between the second bus 118b and the first stub 119, and the power division of the four radiating elements is 4:2:2:1.

In an exemplary embodiment, the line 11 is configured to connect to the radiating element of the antenna. The driving component 2 is a dielectric plate, the dielectric plate includes a phase shift part, and the phase shift part covers at least a part of the line 11. The dielectric plate can slide in the sliding direction X to a third location and a fourth location, and a length of a feeder cable covered by the phase shift part at the third location is different from a length of the feeder cable covered by the phase shift part at the fourth location. In this solution, phase shifting of the radiating element can be implemented by moving the location of the dielectric plate, which is equivalent to implementing phase shifting by moving the location of the driving component 2. Therefore, this embodiment may be combined with the foregoing several embodiments, to implement phase shifting while implementing functions such as beam adjustment or power division, to enrich the application scenarios of the antenna.

In an implementation scenario, in a process in which the dielectric plate (driving component 2) slides from the third location to the fourth location, the plurality of switching components 3 is fastened to the first location or the second location. It may be understood that, in this solution, in a process in which the dielectric plate slides between the third location and the fourth location, the location of the switching component 3 remains unchanged, so that performance of the antenna adjusted via the switching component 3 remains unchanged.

In an exemplary embodiment, there are also a plurality of specific structures and disposing manners of the switching component 3. In an embodiment, the switching component 3 is a translational switching component 3a. FIG. 10 is a diagram of a partially enlarged structure of the signal adjustment component according to an embodiment of the disclosure. FIG. 11a is a diagram of a partial structure of the signal adjustment component according to an embodiment of the disclosure. FIG. 11b is a diagram of a partially exploded structure of the signal adjustment component according to an embodiment of the disclosure. FIG. 11a and FIG. 11b show only one driving combination 100. As shown in FIG. 11a and FIG. 11b, the motherboard 1 is of a fixed structure, may be specifically made of an insulation material, and does not affect a signal of the radiating element of the antenna. The plurality of lines 11 is disposed on the surface of the motherboard 1. The one end of the line 11 is configured to connect to the radiating element of the antenna, and the other end is configured to connect to the connection port of the signal adjustment component. The line may be specifically a feed network, namely, a conductive stripline feed network, and is configured to transmit an electromagnetic signal. A plurality of parallel sliding slots 12 is disposed on the motherboard 1, and are configured to assemble the translational switching component 3a (to simplify the accompanying drawings, in FIG. 11a to FIG. 11b, one translational switching component 3a is used as an example to describe assembly of the translational switching component 3a). The switching component 3 is a translational switching component 3a, and the translational switching component 3a is slidably assembled in the sliding slot 12, so that the translational switching component 3a slides in the sliding slot 12. Specifically, the translational switching component 3a is slidably assembled in the sliding slot 12 via an assembly component in a plurality of manners. In the embodiments shown in FIG. 11a and FIG. 11b, in a possible assembly manner, the assembly component includes a clamping sleeve component 4 and a clamping pin component 5. The clamping sleeve component 4 includes a clamping opening 41, the clamping pin component 5 includes a clamping pin 51, the translational switching component 3a includes a pin hole 32, and the clamping pin 51 passes through the sliding slot 12 and the pin hole 32 and is clamped to the clamping opening 41 of the clamping sleeve component. The clamping pin 51 can slide in the sliding slot 12, to drive the translational switching component 3a to slide. In a further embodiment, each translational switching component 3a is assembled on the motherboard 1 via at least two sliding slots 12. On one hand, a rotation constraint on the translational switching component 3a can be implemented, and on the other hand, sliding stability of the translational switching component 3a can be improved. In this embodiment, the clamping sleeve component includes two clamping openings 41, and the clamping pin component 5 includes two clamping pins 51. In conclusion, one clamping opening 41 and one clamping pin 51 are correspondingly assembled in one sliding slot 12.

Moreover, FIG. 12 is a partially enlarged diagram of the signal adjustment component according to an embodiment of the disclosure. As shown in FIG. 11a, FIG. 11b, and FIG. 12, in an embodiment, the clamping sleeve component 4 includes the two clamping openings 41, each clamping opening 41 is configured to clamp one clamping pin 51, and the translational switching component 3a is slidably assembled on the motherboard 1 via the clamping pin 51 and the clamping sleeve. A spring plate 42 is disposed on a side that is of each clamping opening 41 and that is away from the motherboard 1. This helps improve bonding effect between the translational switching component 3a and the motherboard 1, improve coupling effect between the auxiliary stripline 31 and the line 11, and meet an electrical tolerance requirement.

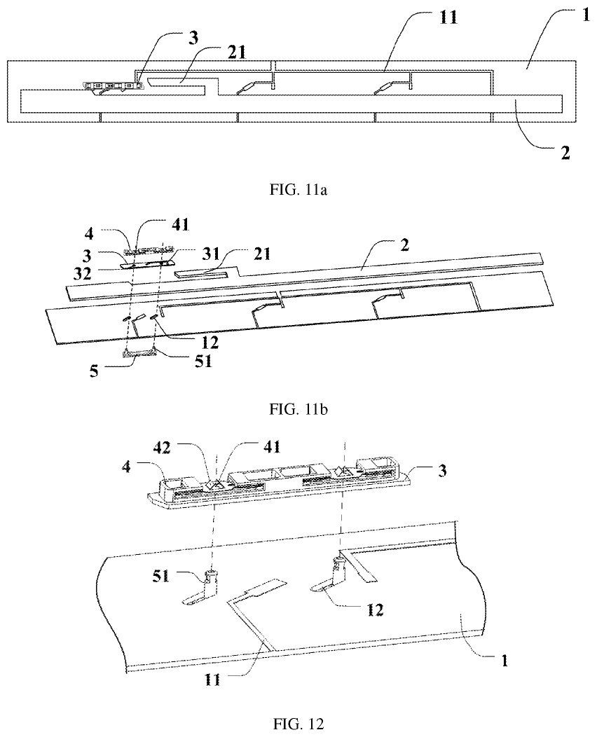

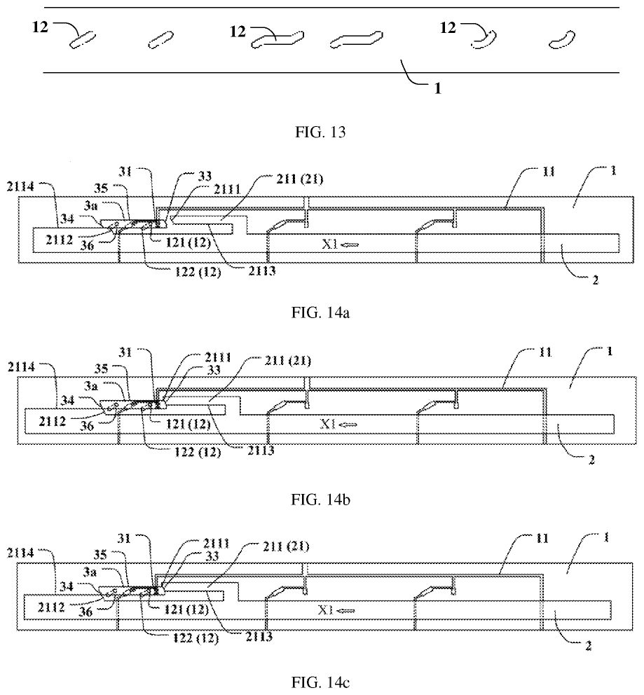

There is a plurality of specific shapes of the sliding slot 12. FIG. 13 is a diagram of several possible structures of the sliding slot 12 of a base according to an embodiment of the disclosure. As shown in FIG. 13, the sliding slot 12 may be a straight-line-shaped sliding slot, a broken-line-shaped sliding slot, or an arc-shaped sliding slot.

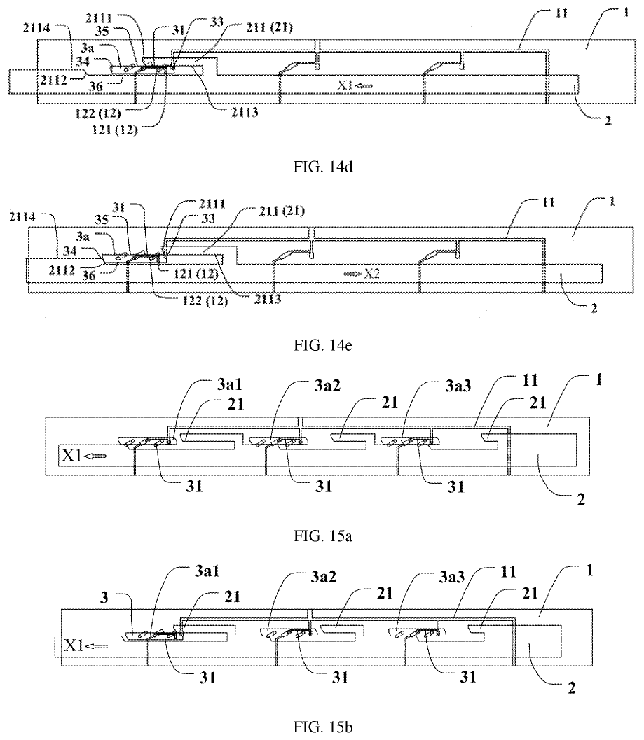

FIG. 14a to FIG. 14e are diagrams of motion processes of the translational switching component of the signal adjustment component according to embodiments of the disclosure. As shown in FIG. 14a to FIG. 14e, for ease of description, it is considered that two ends of the sliding slot 12 are respectively a first end 121 and a second end 122. The driving part 21 includes a first driving part 211, the first driving part 211 includes a first oblique end surface 2111 and a second oblique end surface 2112 that are parallel to a first plane, and the translational switching component 3a includes a third oblique end surface 33 and a fourth oblique end surface 34 that are parallel to the first plane. As shown in FIG. 14a, there is a specific distance between the first oblique end surface 2111 and the third oblique end surface 33, and the driving component 2 slides in the first direction X1. As shown in FIG. 14b, when the driving component 2 slides to a first preset location in the first direction X1, the first oblique end surface 2111 abuts against the third oblique end surface 33, and the driving component 2 continues to slide in the first direction X1, to drive the translational switching component 3a to slide in the sliding slot 12 in a direction from the first end 121 to the second end 122. As shown in FIG. 14c, the translational switching component 3a is located at the first location, and the auxiliary stripline 31 on the translational switching component 3a and the line 11 form the first circuit state (the auxiliary stripline 31 is conducted to the line 11 in the embodiment shown in the figure). When the driving component 2 continues to slide in the first direction X1, the translational switching component 3a remains at the original location, so that the auxiliary stripline 31 and the line 11 remain in the first circuit state. There is a specific distance between the second oblique end surface 2112 and the fourth oblique end surface 34, and the driving component 2 may move in the second direction X2. As shown in FIG. 14d, when the driving component 2 slides to a second preset location in the second direction X2, the second oblique end surface 2112 abuts against the fourth oblique end surface 34, and the driving component 2 continues to slide in the second direction X2, to drive the translational switching component 3a to slide in the sliding slot 12 in a direction from the second end 122 to the first end 121. As shown in FIG. 14e, the translational switching component 3a is located at the second location, and the auxiliary stripline 31 on the translational switching component 3a and the line 11 form the second circuit state (the auxiliary stripline 31 is disconnected from the line 11 in the embodiment shown in the figure). When the driving component 2 continues to slide in the second direction X2, the translational switching component 3a remains at the original location, so that the auxiliary stripline line 31 and the line 11 remain in the second circuit state. The first direction X1 and the second direction X2 are parallel to the sliding direction X, the first direction X1 is opposite to the second direction X2, and the first plane intersects the sliding direction X.

Referring to FIG. 14a to FIG. 14e, the first driving part 211 includes a first limiting surface 2113 and a second limiting surface 2114 that are parallel to the sliding direction X, and the translational switching component 3a includes a third limiting surface 35 and a fourth limiting surface 36 that are arranged in the direction from the first end 121 to the second end 122. The first limiting surface 2113 is configured to fit the third limiting surface 35, so that the translational switching component 3a is limited to a side facing the second end 122. The second limiting surface 2114 is configured to fit the fourth limiting surface 36, so that the translational switching component 3a is limited to a side facing the first end 121. Specifically, when the translational switching component 3a moves to the first location, the first limiting surface 2113 and the third limiting surface 35 abut against each other in a third direction and are capable of sliding relative to each other in the sliding direction X. The third direction is perpendicular to the sliding direction X. In this state, the translational switching component 3a is limited to the side facing the second end 122, so that the auxiliary stripline 31 and the line 11 stably remain in the first circuit state, the translational switching component 3a does not affect sliding of the driving component 2, and the driving component 2 may continue to slide, to drive another switching component 3 to move. When the translational switching component 3a moves to the second location, the second limiting surface 2114 and the fourth limiting surface 36 abut against each other in the third direction and are capable of sliding relative to each other in the sliding direction X. In this state, the translational switching component 3a is limited to the side facing the first end 121, so that the auxiliary stripline 31 and the line 11 stably remain in the second circuit state, the translational switching component 3a does not affect sliding of the driving component 2, and the driving component 2 may continue to slide, to drive another switching component 3 to move.

In an exemplary embodiment, as shown in FIG. 14c, in a state in which the first limiting surface 2113 abuts against the third limiting surface 35, the clamping pin 51 connected to the translational switching component 3a may abut against an end surface of the sliding slot 12 at the second end 122. This improves limiting stability of the translational switching component 3a. Similarly, as shown in FIG. 14e, in a state in which the second limiting surface 2114 abuts against the fourth limiting surface 36, the clamping pin 51 connected to the translational switching component 3a may abut against an end surface of the sliding slot 12 at the first end 121. This improves stability of the translational switching component 3a.

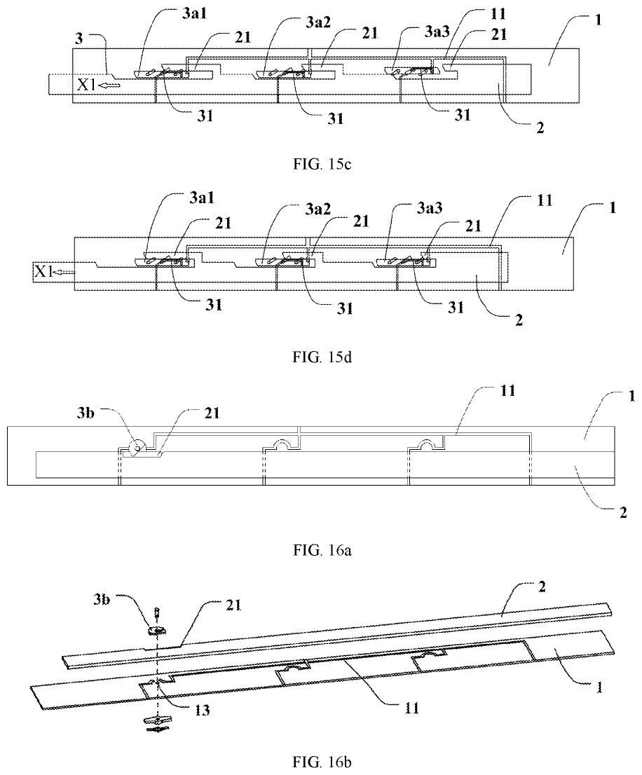

FIG. 15a to FIG. 15d are diagrams of motion processes of the translational switching component of the signal adjustment component according to embodiments of the disclosure. As shown in FIG. 15a to FIG. 15d, when the driving component 2 is located at the preset location, distances between first oblique end surfaces 2111 and third oblique end surfaces 33 in the at least two driving combinations 100 in the first direction X1 are different. A distance between a first oblique end surface 2111 and a third oblique end surface 33 in one driving combination 100 in the first direction X1 is a first distance, a distance between a first oblique end surface 2111 and a third oblique end surface 33 in the other driving combination 100 in the first direction X1 is a second distance, and the first distance is different from the second distance. In this case, in the sliding process of the driving component 2, translational switching components 3a of different driving combinations 100 can be separately driven to move, to implement hierarchical control of the translational switching components 3a of different driving combinations 100 of the signal adjustment component.

In an exemplary embodiment, in the at least two driving combinations 100, lengths of first limiting surfaces 2113 of the driving parts 21 in the sliding direction X are different, and lengths of second limiting surfaces 2114 in the sliding direction X are also different. In this solution, in the at least two driving combination 100, when translational switching components 3a at different levels are controlled to move, the translational switching components 3a can all be in a limited state, thereby improving stability of the signal adjustment component.

In FIG. 15a to FIG. 15d, three levels of switches are used as examples. For ease of description, the three translational switching components 3a are respectively a first switching component 3a1, a second switching component 3a2, and a third switching component 3a3. With reference to FIG. 14a to FIG. 14e, in an embodiment, as shown in FIG. 15a, when the driving component 2 is located at a preset location (for example, the driving component 2 is located on a rightmost side), fourth limiting surfaces 36 of the three translational switching components 3a all abut against corresponding second limiting surfaces 2114, and the translational switching components 3a are limited. A distance between a third oblique end surface 33 of the first switching component 3a1 and a first oblique end surface 2111 of a corresponding first driving part 211, a distance between a third oblique end surface 33 of the second switching component 3a2 and a first oblique end surface 2111 of a corresponding first driving part 211, and a distance between a third oblique end surface 33 of the third switching component 3a3 and a first oblique end surface 2111 of a corresponding first driving part 211 are all different. An auxiliary stripline 31 on each translational switching component 3a is conducted to the corresponding line 11, and is in the first circuit state. The driving component 2 slides in the first direction X1. As shown in FIG. 15b, the first switching component 3a1 is driven by the driving component 2 to slide toward the second end 122 of the sliding slot 12, and a third limiting surface 35 of the first switching component 3a1 abuts against a first limiting surface 2113 of the corresponding first driving part 211 for limiting. In this process, locations of the second switching component 3a2 and the third switching component 3a3 remain unchanged. The auxiliary stripline 31 on the first switching component 3a1 is disconnected from the corresponding line 11, and is in the second circuit state. The auxiliary striplines 31 on the second switching component 3a2 and the third switching component 3a3 are still conducted to the corresponding line 11, and are in the first circuit state. The driving component 2 continues to slide in the first direction X1. As shown in FIG. 15c, the third limiting surface 35 of the first switching component 3a1 and the first limiting surface 2113 of the first driving part 211 keep abutting against each other for limiting and slide relative to each other, the second switching component 3a2 is driven by the driving component 2 to slide toward the second end 122 of the sliding slot 12, and a third limiting surface 35 of the second switching component 3a2 also abuts against a first limiting surface 2113 of the corresponding first driving part 211 for limiting. In this process, locations of first switching component 3a1 and the third switching component 3a3 remain unchanged. The auxiliary striplines 31 of the first switching component 3a1 and the second switching component 3a2 are disconnected from the corresponding line 11, and are in the second circuit state. The auxiliary stripline 31 of the third switching component 3a3 is still conducted to the corresponding line 11, and is in the first circuit state. The driving component 2 continues to slide in the first direction X1. As shown in FIG. 15d, the third limiting surfaces 35 of the first switching component 3a1 and the second switching component 3a2 and the first limiting surfaces 2113 of the respectively corresponding first driving parts 211 keep abutting against each other for limiting and slide relative to each other, the third switching component 3a3 is driven by the driving component 2 to slide toward the second end 122 of the sliding slot 12, and a third limiting surface 35 of the third switching component 3a3 also abuts against a first limiting surface 2113 of the corresponding first driving part 211 for limiting. In this process, the locations of the first switching component 3a1 and the second switching component 3a2 remain unchanged. The auxiliary striplines 31 of the first switching component 3a1, the second switching component 3a2, and the third switching component 3a3 are disconnected from the corresponding line 11, and are all in the second circuit state. Then, the driving component 2 may slide reversely in the second direction X2, and the foregoing process is performed reversely.

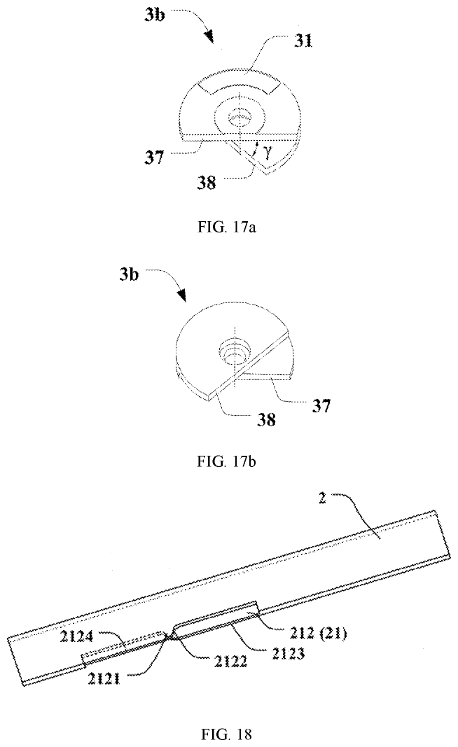

In an exemplary embodiment, the switching component 3 in the disclosure may alternatively be a rotating switching component 3b. FIG. 16a is a diagram of a partial structure of the signal adjustment component according to an embodiment of the disclosure. FIG. 16b is a diagram of a partially exploded structure of the signal adjustment component according to an embodiment of the disclosure. As shown in FIG. 16a and FIG. 16b, the motherboard 1 is of a fixed structure, may be specifically made of an insulation material, and does not affect a signal of the radiating element of the antenna. The plurality of lines 11 is disposed on the surface of the motherboard 1. The line 11 is configured to connect to the radiating element of the antenna, may be specifically a feed network, namely, a conductive stripline feed network, and is configured to transmit an electromagnetic signal. A plurality of mounting holes 13 is disposed on the motherboard 1, and are configured to assemble the rotating switching component 3b (to simplify the accompanying drawings, in FIG. 16a and FIG. 16b, one rotating switching component 3b is used as an example to describe assembly of the rotating switching component 3b). The switching component 3 is the rotating switching component 3b, and the rotating switching component 3b is rotatably assembled on the motherboard 1 via a rotating shaft, so that the rotating switching component 3b rotates along the rotating shaft. FIG. 17a and FIG. 17b are diagrams of structures of the rotating switching component according to embodiments of the disclosure. FIG. 17a is a diagram of a structure on one side of the rotating switching component 3b, and FIG. 17b is a diagram of a structure on the other side of the rotating switching component 3b. As shown in FIG. 17a and FIG. 17b, the rotating switching component 3b includes a first driving plane 37 and a second driving plane 38 that are parallel to an axial direction of the rotating shaft, the first driving plane 37 and the second driving plane 38 intersect at a preset angle γ, and the first driving plane 37 and the second driving plane 38 are sequentially arranged in the axial direction. It may be understood that the rotating switching component 3b includes a two-layer structure arranged in the axial direction. The first driving plane 37 is located at one layer of the structure of the rotating switching component 3b, and the second driving plane 38 is located at the other layer of the structure of the rotating switching component 3b.

Moreover, FIG. 18 is a diagram of a structure of the driving part 21 of the driving component 2 according to an embodiment of the disclosure. As shown in FIG. 18, in an embodiment, the driving part 21 of the driving component 2 includes a second driving part 212, and the second driving part 212 includes a first driving surface 2121 and a second driving surface 2122. The first driving surface 2121 and the second driving surface 2122 are sequentially arranged in the axial direction, and the first driving surface 2121 and the second driving surface 2122 separately extend in a direction away from the rotating shaft. It may be understood that the motherboard 1 includes a two-layer structure arranged in the axial direction. The first driving surface 2121 is located at one layer of the structure of a driving plate, and is configured to abut against the first driving plane 37, to drive the rotating switching component 3b. The second driving surface 2122 is located at the other layer of the structure of the driving plate, and is configured to abut against the second driving plane 38, to drive the rotating switching component 3b.

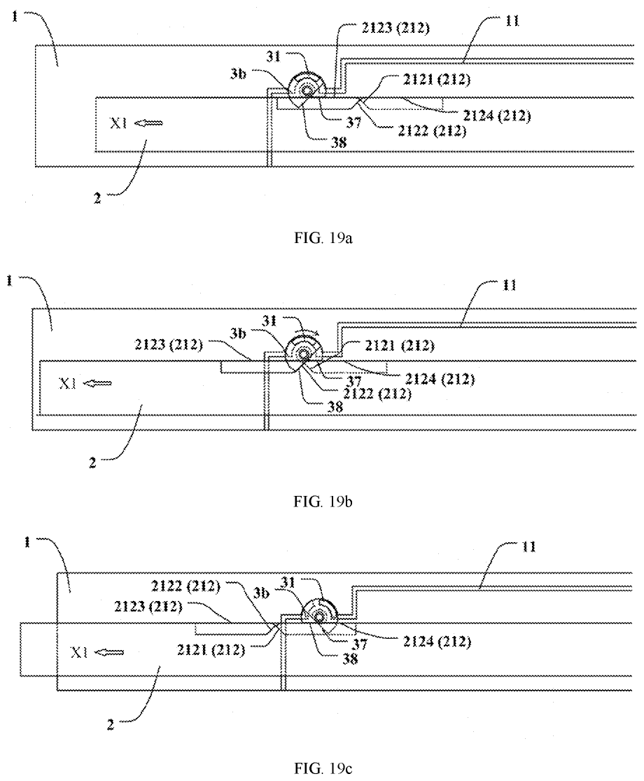

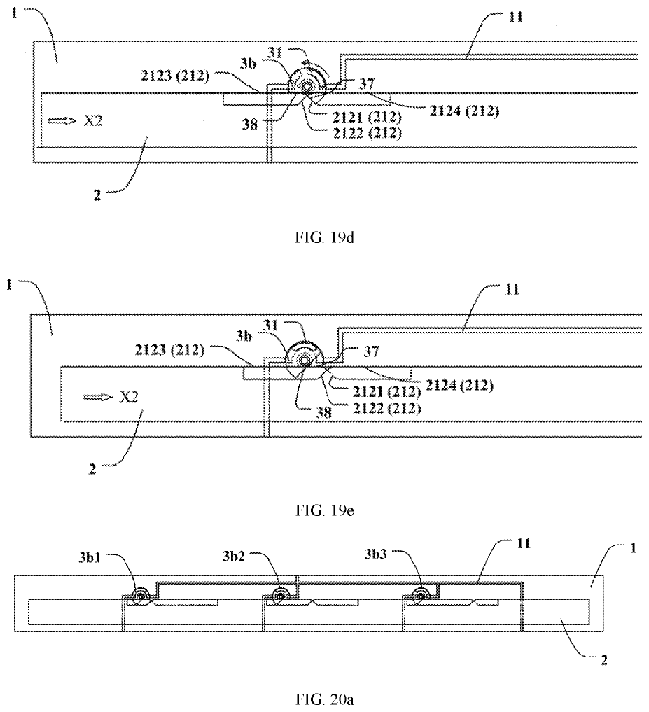

Furthermore, FIG. 19a to FIG. 19e are diagrams of motion processes of the rotating switching component of the signal adjustment component according to embodiments of the disclosure. As shown in FIG. 19a to FIG. 19e, as shown in FIG. 19a, there is a specific distance between the first driving surface 2121 of the second driving part 212 and the first driving plane 37 of the rotating switching component 3b, the driving component 2 slides in the first direction X1, and the rotating switching component 3b remains fixed. Specifically, the rotating switching component 3b may remain at the first location, and in this state, the auxiliary stripline 31 of the rotating switching component 3b is connected to the corresponding line 11 for conduction, and is in the first circuit state. As shown in FIG. 19b, when the driving component 2 slides to a third preset location in the first direction X1, the first driving surface 2121 abuts against the first driving plane 37, and the driving component 2 continues to slide in the first direction X1. As shown in FIG. 19c, the driving component 2 drives the rotating switching component 3b to rotate by the preset angle in a first circumferential direction to the second location, and in this state, the auxiliary stripline 31 of the rotating switching component 3b is disconnected from the corresponding line 11, and is in the second circuit state. As shown in FIG. 19d, when the driving component 2 slides to a fourth preset location in the second direction X2, the second driving surface 2122 abuts against the second driving plane 38, and the driving component 2 continues to slide in the second direction X2, to drive the rotating switching component 3b to rotate by the preset angle in a second circumferential direction to the first location, and the auxiliary stripline 31 of the rotating switching component 3b is connected to the corresponding line 11 for conduction, and is in the first circuit state. As shown in FIG. 19e, the rotating switching component 3b remains at the first location, and the auxiliary stripline 31 of the rotating switching component 3b is connected to the corresponding line 11 for conduction, and is in the first circuit state. The first circumferential direction is opposite to the second circumferential direction.

Moreover, referring to FIG. 18, and FIG. 19a to FIG. 19e, in order to improve motion stability of the rotating switching component 3b, the second driving part 212 includes a fifth limiting surface 2123 and a sixth limiting surface 2124 that are parallel to the sliding direction X, and the fifth limiting surface 2123 and the sixth limiting surface 2124 are sequentially arranged in the axial direction. As shown in FIG. 19a, when the rotating switching component 3b rotates to the first location, the fifth limiting surface 2123 is parallel to and abuts against the first driving plane 37. In this state, the fifth limiting surface 2123 and the first driving plane 37 can slide relative to each other, and the rotating switching component 3b cannot rotate. This implements circumferential limiting of the rotating switching component 3b. In this solution, the auxiliary stripline 31 and the line 11 stably remain in the first circuit state, the rotating switching component 3b does not affect sliding of the driving component 2, and the driving component 2 may continue to slide, to drive another switching component 3 to move. As shown in FIG. 19c, when the rotating switching component 3b rotates to the second location, the sixth limiting surface 2124 is parallel to and abuts against the second driving plane 38. In this state, the sixth limiting surface 2124 and the second driving plane 38 can slide relative to each other, and the rotating switching component 3b cannot rotate. This implements circumferential limiting of the rotating switching component 3b. In this solution, the auxiliary stripline 31 and the line 11 stably remain in the second circuit state, the rotating switching component 3b does not affect sliding of the driving component 2, and the driving component 2 may continue to slide, to drive another switching component 3 to move.

According to an exemplary embodiment shown in FIG. 18 and FIG. 19a to FIG. 19e, the fifth limiting surface 2123 is connected to the first driving surface 2121, and the first driving plane 37 may continuously move between the fifth limiting surface 2123 and the first driving surface 2121. When the first driving plane 37 of the rotating switching component 3b slides from the fifth limiting surface 2123 to the first driving surface 2121, the first driving plane 37 is separated from the fifth limiting surface 2123, a degree of freedom of the rotating switching component 3b is released, and the rotating switching component 3b moves along the first driving surface 2121, to drive the rotating switching component 3b to rotate. The sixth limiting surface 2124 is connected to the second driving surface 2122, and the second driving plane 38 may continuously move between the sixth limiting surface 2124 and the second driving surface 2122. When the second driving plane 38 of the rotating switching component 3b slides from the sixth limiting surface 2124 to the second driving surface 2122, the second driving plane 38 is separated from the sixth limiting surface 2124, the degree of freedom of the rotating switching component 3b is released, and the rotating switching component 3b moves along the first driving surface 2121, to drive the rotating switching component 3b to rotate.

Moreover, the first driving surface 2121 and the second driving surface 2122 of the second driving part 212 of the driving component 2 are axisymmetrically disposed, and a symmetry axis of the first driving surface 2121 and the second driving surface 2122 is parallel to the axial direction. Fitting between the second driving part 212 and the rotating switching component 3b in a case in which the driving component 2 slides in the first direction X1 is the same as that between the second driving part 212 and the rotating switching component 3b in a case in which the driving component 2 slides in the second direction X2. This helps simplify a structure of the second driving part 212 and a structure of the rotating switching component 3b.

There is a plurality of specific shapes of the first driving surface 2121 and the second driving surface 2122. For example, the first driving surface 2121 may be at least one of a plane, a paraboloid, or a semi-cylindrical surface. The second driving surface 2122 may be at least one of a plane, a paraboloid, or a semi-cylindrical surface.

In an exemplary embodiment, the auxiliary stripline 31 disposed on the rotating switching component 3b may be specifically an arc-shaped auxiliary stripline 31, an area that is of the line 11 and that corresponds to the rotating switching component 3b includes an arc-shaped line, and the arc-shaped auxiliary stripline and the arc-shaped line form the first circuit state or the second circuit state. Specifically, the arc-shaped auxiliary stripline 31 is concentric with the rotating shaft of the rotating switching component 3b, so that the arc-shaped auxiliary stripline 31 rotates with rotation of the rotating switching component. This helps improve reliability of a connection between the arc-shaped auxiliary stripline 31 and the arc-shaped line.

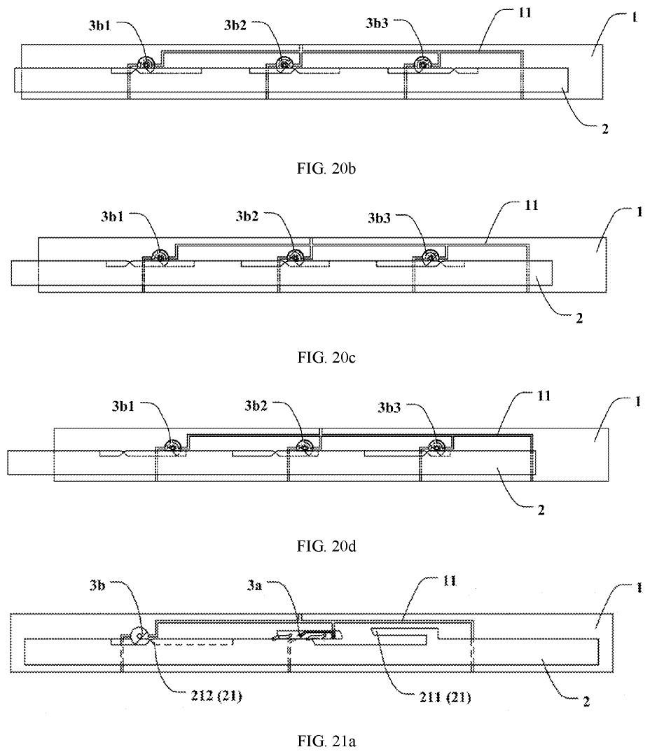

Moreover, FIG. 20a to FIG. 20d are diagrams of motion processes of the rotating switching component 3b of the signal adjustment component according to embodiments of the disclosure. As shown in FIG. 20a to FIG. 20d, when the driving component 2 is located at the preset location, distances between first driving surfaces 2121 and rotating shafts of rotating switching components 3b in the at least two driving combinations 100 in the first direction X1 are different. A distance between a first driving surface 2121 and a rotating shaft of a rotating switching component 3b in one driving combination 100 in the first direction X1 is a third distance, a distance between a first driving surface 2121 and a rotating shaft of a rotating switching component 3b in the other driving combination 100 in the first direction X1 is a fourth distance, and the third distance is different from the fourth distance. In this case, in the sliding process of the driving component 2, rotating switching components 3b of different driving combinations 100 can be separately driven to move, to implement hierarchical control of the rotating switching components 3b of different driving combinations 100 of the signal adjustment component.

In an exemplary embodiment, in the at least two driving combinations 100, lengths of fifth limiting surfaces 2123 of the driving parts 21 in the sliding direction X are different, and lengths of sixth limiting surfaces 2324 in the sliding direction X are also different. In this solution, in the at least two driving combination 100, when rotating switching components 3b at different levels are controlled to move, the rotating switching components 3b can all be in a limited state, thereby improving the stability of the signal adjustment component.

Furthermore, in FIG. 20a to FIG. 20d, three levels of switches are used as examples. For ease of description, the three rotating switching components 3b are respectively a fourth switching component 3b1, a fifth switching component 3b2, and a sixth switching component 3b3. Referring to FIG. 19a to FIG. 19e, in an embodiment, as shown in FIG. 20a, when the driving component 2 is located at a preset location, first driving planes 37 of the three rotating switching components 3b all abut against corresponding fifth limiting surfaces 2123, and the rotating switching components 3b are limited. A distance between a rotating shaft of the fourth switching component 3b1 and a first driving surface 2121 of a corresponding second driving part 212, a distance between a rotating shaft of the fifth switching component 3b2 and a first driving surface 2121 of a corresponding second driving part 212, and a distance between a rotating shaft of the sixth switching component 3b3 and a first driving surface 2121 of a corresponding second driving part 212 are all different. An auxiliary stripline 31 on each rotating switching component 3b is conducted to the corresponding line 11, and is in the first circuit state. The driving component 2 slides in the first direction X1, and the first driving plane 37 and the fifth limiting surface 2123 of the fourth switching component 3b1 slide relative to each other until the first driving plane 37 is opposite to the first driving surface 2121, to release a degree of freedom of rotation of the fourth switching component 3b1, and drive the fourth switching component 3b1 to rotate. In the process, the first driving planes 37 of the fifth switching component 3b2 and the sixth switching component 3b3 respectively slide relative to the corresponding fifth limiting surfaces 2123. As shown in FIG. 20b, a second driving plane 38 of the fourth switching component 3b1 abuts against a sixth limiting surface 2124 of the corresponding second driving part 212 for limiting, the auxiliary stripline 31 on the fourth switching component 3b1 is disconnected from the corresponding line 11, and is in the second circuit state, locations of the fifth switching component 3b2 and the sixth switching component 3b3 remain unchanged, and the auxiliary striplines 31 of the fifth switching component 3b2 and the sixth switching component 3b3 are still conducted to the corresponding line 11, and are in the first circuit state. The driving component 2 continues to slide in the first direction X1, and the second driving plane 38 of the fourth switching component 3b1 and the sixth limiting surface 2124 of the corresponding second driving part 212 abut against each other and slide relative to each other. The first driving plane 37 of the fifth switching component 3b2 and the fifth limiting surface 2123 of the corresponding second driving part 212 slide relative to each other until the first driving plane 37 is opposite to the first driving surface 2121, to release a degree of freedom of rotation of the fifth switching component 3b2, and drive the fifth switching component 3b2 of the corresponding second driving part 212 to rotate. The first driving plane 37 of the sixth switching component 3b3 slides relative to the corresponding fifth limiting surface 2123. As shown in FIG. 20c, a second driving plane 38 of the fifth switching component 3b2 also abuts against a sixth limiting surface 2124 of the corresponding second driving part 212 for limiting, and the auxiliary stripline lines 31 of the fourth switching component 3b1 and the fifth switching component 3b2 are disconnected from the corresponding line 11, and are in the second circuit state. The auxiliary stripline 31 of the sixth switching component 3b3 is still conducted to the corresponding line 11, and is in the first circuit state. The driving component 2 continues to slide in the first direction X1, and the second driving planes 38 of the fourth switching component 3b1 and the fifth switching component 3b2 and the sixth limiting surfaces 2324 of the respectively corresponding first driving parts 211 keep abutting against each other for limiting and slide relative to each other. The first driving plane 37 of the sixth switching component 3b3 and the fifth limiting surface 2123 of the corresponding second driving part 212 slide relative to each other until the first driving plane 37 is opposite to the first driving surface 2121, to release a degree of freedom of rotation of the sixth switching component 3b3, and drive the sixth switching component 3b3 to rotate until the second driving plane 38 of the sixth switching component 3b3 also abuts against the sixth limiting surface 2124 of the corresponding second driving part 212. As shown in FIG. 20d, the auxiliary striplines 31 of the fourth switching component 3b1, the fifth switching component 3b2, and the sixth switching component 3b3 are disconnected from the corresponding line 11, and are all in the second circuit state. Then, the driving component 2 slides reversely in the second direction X2, and the foregoing process is performed reversely.

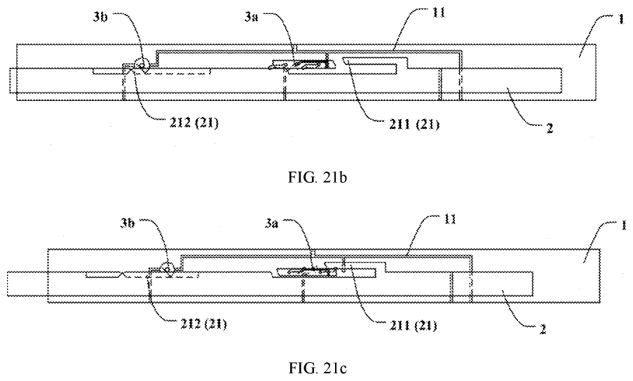

In another embodiment, the signal adjustment component may alternatively include both the translational switching component 3a and the rotating switching component 3b. FIG. 21a to FIG. 21c are diagrams of motion processes of the signal adjustment component according to embodiments of the disclosure. In the figure, an example in which the signal adjustment component includes one translational switching component 3a and one rotating switching component 3b is used, and in actual application, a quantity of translational switching components 3a and a quantity of rotating switching components 3b may be selected and designed based on a requirement. In this embodiment, a distance between the first driving surface 2121 of the second driving part 212 and the rotating shaft of the rotating switching component 3b in the first direction X1 is different from a distance between the first oblique end surface 2111 of the first driving part 211 and the third oblique end surface 33 of the translational switching component 3a in the first direction X1, so that the rotating switching component 3b and the translational switching component 3a are decoupled from each other, to implement hierarchical control of the rotating switching component 3b and the translational switching component 3a. For structures and motion processes of the rotating switching component 3b and the translational switching component 3a, refer to the foregoing embodiments. Details are not described herein again.

The foregoing descriptions are merely specific implementations of the disclosure, but are not intended to limit the protection scope of the disclosure. Any variation or replacement readily figured out by a person skilled in the art within the technical scope disclosed in the disclosure shall fall within the protection scope of the disclosure. Therefore, the protection scope of the disclosure shall be subject to the protection scope of the claims.

1. A signal adjustment component, comprising:
a motherboard;
a driving component;
a plurality of switching components;
wherein a line is disposed on the motherboard;
wherein each switching component of the plurality of switching components is movably assembled on the motherboard;
an auxiliary stripline disposed on each switching component of the plurality of switching components;
wherein each switching component of the plurality of switching components is configured to change a connection status with the line via the auxiliary stripline during motion;
wherein the driving component is slidably assembled on the motherboard;
wherein the driving component further comprises a plurality of driving parts corresponding to the plurality of switching components in a one-to-one ratio;
wherein a driving part of the plurality of driving parts and a switching component of the plurality of switching components that correspond to each other form a driving combination;
wherein the driving part in the driving combination is configured to drive the switching component to move;
wherein the plurality of switching components is arranged in a sliding direction of the driving component;
wherein the plurality of driving parts is arranged in the sliding direction;
wherein distances between the plurality of the switching components and the plurality of driving parts in at least two driving combinations in the sliding direction are different when the driving component is located at a preset location; and,
wherein when the driving component slides to different locations in the sliding direction, the plurality of the switching components in different driving combinations are driven to move.

2. The signal adjustment component according to claim 1, wherein the switching component further comprises a translational switching component;
a plurality of sliding slots disposed on the motherboard;
wherein the translational switching component is slidably assembled in the sliding slot;
wherein the two ends of the sliding slot are respectively a first end and a second end;
wherein the driving part comprises a first driving part having a first oblique end surface and a second oblique end surface parallel to a first plane;
wherein the translational switching component comprises a third oblique end surface and a fourth oblique end surface parallel to the first plane;
wherein the first oblique end surface abuts against the third oblique end surface and the driving component continues to slide in the first direction when the driving component slides to a first preset location in a first direction; to drive the translational switching component to slide in the sliding slot in a direction from the first end to the second end;
wherein the second oblique end surface abuts against the fourth oblique end surface and the driving component continues to slide in the second direction when the driving component slides to a second preset location in a second direction; to drive the translational switching component to slide in the sliding slot in a direction from the second end to the first end; and,
wherein the first direction and the second direction are parallel to the sliding direction, the first direction is opposite to the second direction, and the first plane intersects the sliding direction.

3. The signal adjustment component according to claim 2, wherein distances between first oblique end surfaces and third oblique end surfaces in the at least two driving combinations in the first direction are different when the driving component is located at the preset location.

4. The signal adjustment component according to claim 2, wherein the first driving part further comprises a first limiting surface and a second limiting surface parallel to the sliding direction;
wherein the translational switching component further comprises a third limiting surface and a fourth limiting surface arranged in the direction from the first end to the second end;
wherein the first limiting surface and the third limiting surface abut against each other in a third direction and are capable of sliding relative to each other in the sliding direction when the translational switching component moves to a first location; and,
wherein the second limiting surface and the fourth limiting surface abut against each other in the third direction and are capable of sliding relative to each other in the sliding direction when the translational switching component moves to a second location; and,
wherein the third direction is perpendicular to the sliding direction.

5. The signal adjustment component according to claim 4, wherein in the at least two driving combinations, lengths of first limiting surfaces of the driving parts in the sliding direction are different, and wherein the lengths of second limiting surfaces in the sliding direction are different.

6. The signal adjustment component according to claim 1, wherein the switching component comprises a rotating switching component;
wherein the rotating switching component is rotatably assembled on the motherboard via a rotating shaft;
wherein the rotating switching component comprises a first driving plane and a second driving plane that are parallel to an axial direction of the rotating shaft;
wherein the first driving plane and the second driving plane intersect at a preset angle;
wherein the first driving plane and the second driving plane are sequentially arranged in the axial direction;
wherein the driving part comprises a second driving part;
wherein the second driving part comprises a first driving surface and a second driving surface;
wherein first driving surface and the second driving surface are sequentially arranged in the axial direction;
wherein the first driving surface and the second driving surface separately extend in a direction away from the rotating shaft;
wherein the first driving surface abuts against the first driving plane, and the driving component continues to slide in the first direction to drive the rotating switching component to rotate by the preset angle in a first circumferential direction to the first location when the driving component slides to a third preset location in the first direction;
wherein the second driving surface abuts against the second driving plane, and the driving component continues to slide in the second direction to drive the rotating switching component to rotate by the preset angle in a second circumferential direction to the second location when the driving component slides to a fourth preset location in the second direction; and,
wherein the first circumferential direction is opposite to the second circumferential direction.

7. The signal adjustment component according to claim 6, wherein the distances between first driving surfaces and rotating shafts in the at least two driving combinations in the first direction are different when the driving component is located at the preset location.

8. The signal adjustment component according to claim 6, wherein the first driving surface and the second driving surface of the second driving part are axisymmetrically disposed, and wherein a symmetry axis of the first driving surface and the second driving surface is parallel to the axial direction.

9. The signal adjustment component according to claim 6, wherein the driving part further comprises a fifth limiting surface and a sixth limiting surface that are parallel to the sliding direction;
wherein the fifth limiting surface and the sixth limiting surface are sequentially arranged in the axial direction;
wherein the fifth limiting surface is parallel to and abuts against the first driving plane when the rotating switching component rotates to the first location; and,
wherein the sixth limiting surface is parallel to and abuts against the second driving plane when the rotating switching component rotates to the second location.

10. The signal adjustment component according to claim 9, wherein the fifth limiting surface is connected to the first driving surface, and wherein the sixth limiting surface is connected to the second driving surface.

11. The signal adjustment component according to claim 6, wherein the auxiliary stripline disposed on the rotating switching component has an arch shape and configuration;
wherein an area that is of the line and that corresponds to the rotating switching component comprises an arc-shaped line, and wherein the arc-shaped auxiliary stripline and the arc-shaped line form a first circuit state or a second circuit state.

12. The signal adjustment component according to claim 1, wherein one line comprises a first stripline and a second stripline disconnected from the first stripline;
wherein the first stripline is configured to connect to a connection port of the signal adjustment component, and the second stripline is configured to connect to a radiating element of an antenna; and
wherein the auxiliary stripline is connected to the first stripline and the second stripline in the first circuit state; and,
wherein the auxiliary stripline is disconnected from the first stripline and/or the second stripline in the second circuit state.

13. The signal adjustment component according to claim 1, wherein the line is configured to connect to a radiating element of an antenna;
wherein one end of the auxiliary stripline is configured to connect to a connection port of the signal adjustment component, and wherein the other end of the auxiliary stripline is in lap joint with the line; and,
wherein the auxiliary stripline is in lap joint with a first connection point of the line in the first circuit state; and,
wherein the auxiliary stripline is in lap joint with a second connection point of the line in the second circuit state.

14. The signal adjustment component according to claim 1, wherein the line comprises a third stripline and a fourth stripline that are disconnected from each other;
wherein the third stripline is configured to connect to a connection port of the signal adjustment component;
wherein the fourth stripline is configured to connect to a radiating element of an antenna; and,
wherein one end of the auxiliary stripline is in lap joint with the third stripline, and the other end is in lap joint with the fourth stripline, so that the third stripline is electrically connected to the fourth stripline; and,
wherein the auxiliary stripline is in lap joint with a third connection point of the third stripline, and the auxiliary stripline is in lap joint with a fourth connection point of the fourth stripline in the first circuit state; and,
wherein the auxiliary stripline is in lap joint with a fifth connection point of the third stripline, and the auxiliary stripline is in lap joint with a sixth connection point of the fourth stripline in the second circuit state.

15. The signal adjustment component according to claim 1, wherein the line comprises a bus, a first stub, and a second stub, one end of the bus is configured to connect to a connection port of the signal adjustment component;
wherein the first stub and the second stub are connected in parallel and are connected to the other end of the bus;
wherein the first stub and the second stub are respectively configured to connect to different radiating elements of an antenna, and a cross-sectional area of the auxiliary stripline is greater than a cross-sectional area of the line; and,
wherein the auxiliary stripline covers a connection region between the bus and the first stub, and is connected to the line in the first circuit state; and,
wherein the auxiliary stripline is disconnected from the line in the second circuit state.

16. The signal adjustment component according to claim 1, wherein the line is configured to connect to the radiating element of the antenna;
wherein the driving component is a dielectric plate comprising a phase shift part covering at least a part of the line;
wherein the dielectric plate slides in the sliding direction to a third location and a fourth location, and wherein a length of the line covered by the phase shift part at the third location is different from a length of the line covered by the phase shift part at the fourth location.

17. The signal adjustment component according to claim 16, wherein in a process in which the dielectric plate slides from the third location to the fourth location, the plurality of switching components is fastened to the first location or the second location.

18. A signal adjustment component, comprising;
a motherboard;
a driving component;
a plurality of switching components;
wherein a line is disposed on the motherboard;
wherein each switching component of the plurality of switching components is movably assembled on the motherboard;
an auxiliary stripline is disposed on each switching component of the plurality of switching components;
wherein the driving component is slidably assembled on the motherboard;
wherein the driving component further comprises a plurality of driving parts corresponding to the plurality of switching components in a one-to-one ration;
wherein a driving part of the plurality of driving parts and a switching component of the plurality of switching components that correspond to each other form a driving combination;
wherein distances between switching components and driving parts in different driving combinations in a sliding direction are different;
wherein the driving component drives the plurality of switching components to sequentially move in a sliding process, so that connection statuses between auxiliary striplines of the plurality of switching components and the line sequentially change; and,
wherein a connection status between an auxiliary stripline of another switching component and the line remains unchanged when a connection status between an auxiliary stripline of one of the plurality of switching components and the line changes.

19. An antenna, comprising:
a radiating element; and,
a signal adjustment component
comprising:
a motherboard;
a driving component;
a plurality of switching components;
wherein a line is disposed on the motherboard;
wherein each switching component of the plurality of switching components is movably assembled on the motherboard;
an auxiliary stripline is disposed on each switching component of the plurality of switching components;
wherein each switching component of the plurality of switching components is configured to change a connection status with the line via the auxiliary stripline during motion;
wherein the driving component is slidably assembled on the motherboard;
wherein driving component further comprises a plurality of driving parts corresponding to the plurality of switching components in a one-to-one ration;
wherein a driving part of the plurality of driving parts and a switching component of the plurality of switching components that correspond to each other form a driving combination;
wherein the driving part in the driving combination is configured to drive the switching component to move;
wherein the plurality of switching components is arranged in a sliding direction of the driving component;
wherein the plurality of driving parts is arranged in the sliding direction;
wherein distances between switching components and driving parts in at least two driving combinations in the sliding direction are different when the driving component is located at a preset location;
wherein switching components in different driving combinations are driven to move when the driving component slides to different locations in the sliding direction; and,
wherein the radiating element is connected to a line of the signal adjustment component.

20. A communication device, comprising;
an antenna;
wherein the antenna comprises a radiating element and a signal adjustment component;
wherein the signal adjustment component comprises a motherboard, a driving component, and a plurality of switching components;
wherein a line is disposed on the motherboard;
wherein each switching component is movably assembled on the motherboard;
an auxiliary stripline is disposed on each switching component of the plurality of switching components;
wherein each switching component of the plurality of switching components is configured to change a connection status with the line via the auxiliary stripline during motion;
wherein the driving component is slidably assembled on the motherboard;
wherein the driving component further comprises a plurality of driving parts corresponding to the plurality of switching components in a one-to-one ratio;
wherein a driving part of the plurality of driving parts and one switching component of the plurality of switching components that correspond to each other form a driving combination;
wherein the driving part in the driving combination is configured to drive the switching component to move;
wherein the plurality of switching components is arranged in a sliding direction of the driving component;
wherein the plurality of driving parts is arranged in the sliding direction;
wherein distances between switching components and driving parts in at least two driving combinations in the sliding direction are different when the driving component is located at a preset location;
wherein switching components in different driving combinations are driven to move when the driving component slides to different locations in the sliding direction;
wherein the radiating element is connected to a line of the signal adjustment component;
and,
wherein the communication device further comprises a radio frequency processing circuit, and wherein the line of the signal adjustment component of the antenna is connected to the radio frequency processing circuit.
